(19) United States
(12) Patent Application Publication
(10) Pub. No.: US 2026/0076068 A1
(43) Pub. Date: Mar. 12, 2026

(54) DISPLAY DEVICE, ELECTRONIC DEVICE INCLUDING THE DISPLAY DEVICE, AND METHOD OF MANUFACTURING THE DISPLAY DEVICE

(71) Applicant: Samsung Display Co., Ltd., Yongin-si (KR)

(72) Inventors: Seongjin Hwang, Yongin-si (KR); Byunghoon Kang, Yongin-si (KR); Sanghoon Kim, Yongin-si (KR); Seungho Kim, Yongin-si (KR); Jingyu Sim, Yongin-si (KR)

(21) Appl. No.: 19/053,151

(22) Filed: Feb. 13, 2025

(30) Foreign Application Priority Data
Sep. 6, 2024 (KR) 10-2024-0121785

(51) Int. Cl. H10K 59/80; H10K 59/12

(52) U.S. Cl. CPC H10K 59/873; H10K 59/1201

(57) ABSTRACT

A display device including a lower cover including a glass layer, a first resin layer on a first surface of the glass layer, and a second resin layer on a second surface, is the second surface being an opposite surface of the first surface, and a display layer on the lower cover and including a plurality of light-emitting elements, wherein the lower cover includes a folding portion that is foldable around one axis, the glass layer includes a glass pattern on the folding portion, and a lateral surface of the glass layer extending between the first surface and the second surface and defining a circumference of the glass layer, the lateral surface of the glass layer being covered by at least one of the first resin layer or the second resin layer.

### CROSS-REFERENCE TO RELATED APPLICATION

The present application claims priority to and the benefit of Korean Patent Application No. 10-2024-0121785, filed on Sep. 6, 2024, in the Korean Intellectual Property Office, the entire disclosure of which is incorporated herein by reference.

### BACKGROUND

### 1. Field

Embodiments of the present disclosure described herein are related to a display device, an electronic device including the display device, and a method of manufacturing the display device.

### 2. Description of the Related Art

To support one or more suitable functions, electronic devices may include a display device for providing a user with visual information such as images. Recently, as the components (parts) configured to drive display devices have become miniaturized or decreased in size, the proportion of display devices in electronic devices has gradually increased. Additionally, there is ongoing development of display devices and electronic devices with bendable or foldable structures that can transition from a flat state to a set or preset angle. These bendable or foldable display devices may include a lower cover that supports (for supporting) a display layer configured to display or show images.

The information disclosed in this Background section is intended to enhance understanding of the background of the disclosure and therefore it may contain information that does not constitute prior art.

### SUMMARY

A lower cover of a display device may have structural characteristics that allow bending or folding. For example, a portion of the lower cover in a region adjacent to a bending or folding axis may have a thickness different from a thickness of another portion of the lower cover. In some examples, the lower cover in a region adjacent to a bending or folding axis may include a preset pattern.

In some examples, materials such as metal or carbon fiber reinforced plastic (CFRP) have been used for the lower cover (e.g., as a material of the lower cover). When processing such materials to achieve or implement the aforementioned thickness or pattern, issues may arise, such as difficulty in processing and maintaining surface quality.

Aspects according to one or more embodiments of the present disclosure are directed toward a display device, an electronic device, and a method of manufacturing the display device.

Additional aspects will be set forth in part in the description which follows and, in part, will be apparent from the description, or may be learned by practice of the presented embodiments of the disclosure.

According to one or more embodiments, a display device includes a lower cover including a glass layer, a first resin layer arranged on a first surface of the glass layer, and a second resin layer arranged on a second surface, the second surface being an opposite surface of the first surface, and a display layer arranged on the lower cover and including a plurality of light-emitting elements, wherein the lower cover includes a folding portion that is foldable around one axis, the glass layer includes a glass pattern arranged on the folding portion, and a lateral surface of the glass layer extending between the first surface and the second surface and defining a circumference of the glass layer, the lateral surface of the glass layer being covered by at least one of the first resin layer or the second resin layer.

In one or more embodiments, the glass pattern may include a groove, and a portion of the second resin layer may be arranged in the groove of the glass pattern.

In one or more embodiments, the groove may pass through the glass layer, and the first resin layer and the second resin layer may be in contact with each other in a region overlapping the groove.

In one or more embodiments, the lateral surface of the glass layer may be covered by the second resin layer, and the first resin layer and the second resin layer may be in contact with each other at the lateral surface of the glass layer.

In one or more embodiments, the first resin layer may include a protrusion arranged in a region adjacent to the lateral surface of the glass layer, wherein the protrusion protrudes toward the second resin layer.

In one or more embodiments, the display layer may be arranged on the first resin layer.

According to one or more embodiments, an electronic device includes a display device and a cover window arranged on the display device, wherein the display device includes a lower cover including a glass layer, a first resin layer arranged on a first surface of the glass layer, and a second resin layer arranged on a second surface, the second surface being an opposite surface of the first surface, and a display layer arranged on the lower cover and including a plurality of light-emitting elements, wherein the lower cover includes a folding region that is foldable around one axis, the glass layer includes a glass pattern arranged in the folding region, and a lateral surface of the glass layer extending between the first surface and the second surface and defining a circumference of the glass layer, the lateral surface being covered by at least one of the first resin layer or the second resin layer.

According to one or more embodiments, a method of manufacturing a display device includes forming a first pattern and a second pattern on a mother glass substrate by laser processing the mother glass substrate, arranging a first material layer on a first surface of the mother glass substrate that is laser processed, forming a first groove and a second groove in a second surface opposite to the first surface of the mother glass substrate on which the first material layer is arranged, wherein the first groove and the second groove respectively overlap the first pattern and the second pattern, arranging a second material layer on the second surface of the mother glass substrate in which the first groove and the second groove are arranged, and cutting the first material layer and the second material layer along the first groove.

In one or more embodiments, in the arranging of the second material layer, a portion of the second material layer may be arranged in the first groove or the second groove.

In one or more embodiments, at least one of the first groove or the second groove may pass through the mother glass substrate.

In one or more embodiments, the first material layer and the second material layer may be in contact with each other in a region overlapping the first groove or the second groove.

In one or more embodiments, an etching selectivity of a portion of the mother glass substrate on which the first pattern and the second pattern are arranged may be different from an etching selectivity of another portion of the mother glass substrate.

In one or more embodiments, the method may further include healing the first surface of the mother glass substrate that is laser processed.

In one or more embodiments, in the healing of the first surface of the mother glass substrate, a third groove overlapping the first pattern may be arranged, and in the arranging of the first material layer, a portion of the first material layer may be arranged in the third groove.

In one or more embodiments, the method may further include healing the second surface of the mother glass substrate in which the first groove and the second groove are arranged.

In one or more embodiments, in the healing of the second surface of the mother glass substrate, a size of the first groove may be increased.

In one or more embodiments, the method may further include slimming the mother glass substrate.

In one or more embodiments, the method may further include arranging a display layer on the first surface of the mother glass substrate.

In one or more embodiments, in the cutting of the first material layer and the second material layer, the display layer may be cut together.

After the first material layer and the second material layer are cut, the display layer may be arranged.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic cross-sectional view of an electronic device according to one or more embodiments;

FIG. 2 is a schematic exploded perspective view of an electronic device according to one or more embodiments;

FIG. 3 is a schematic cross-sectional view of an electronic device according to one or more embodiments;

FIG. 4 is a schematic cross-sectional view of a portion of an electronic device according to one or more embodiments;

FIG. 5 is a perspective view of a lower cover according to one or more embodiments;

FIG. 6 is a cross-sectional view of a lower cover according to one or more embodiments;

FIG. 7 is a cross-sectional view of a lower cover according to one or more embodiments;

FIG. 8 is a cross-sectional view of a lower cover according to one or more embodiments;

FIG. 9 is a cross-sectional view of a lower cover according to one or more embodiments;

FIG. 10 is a plan view of a portion of a lower cover according to one or more embodiments;

FIG. 11 is a plan view of a portion of a lower cover according to one or more embodiments;

FIG. 12 is a plan view of a portion of a lower cover according to one or more embodiments;

FIG. 13 is a cross-sectional view of a lower cover according to one or more embodiments;

FIG. 14 is a cross-sectional view of a lower cover according to one or more embodiments;

FIG. 15 is a cross-sectional view of a lower cover according to one or more embodiments;

FIG. 16 is a cross-sectional view of a lower cover according to one or more embodiments;

FIG. 17 is a plan view of a portion of a lower cover according to one or more embodiments;

FIG. 18 is a plan view of a portion of a lower cover according to one or more embodiments;

FIG. 19 is a plan view of a portion of a lower cover according to one or more embodiments;

FIG. 20 is a cross-sectional view of a lower cover according to one or more embodiments;

FIG. 21 is a cross-sectional view of a lower cover according to one or more embodiments;

FIG. 22 is a cross-sectional view of a lower cover according to one or more embodiments;

FIG. 23 is a schematic cross-sectional view of a display device according to one or more embodiments;

FIGS. 24A, 24B, 24C, 24D, 24E, 24F, 24G, 24H, and 24I are schematic views showing respective processes of a method of manufacturing a display device according to one or more embodiments; and

FIG. 25 is a schematic view showing a process of a method of manufacturing a display device according to one or more embodiments.

### DETAILED DESCRIPTION

Reference will now be made in more detail to one or more embodiments, examples of which are illustrated in the accompanying drawings, wherein like reference numerals refer to like elements throughout, and duplicative descriptions thereof may not be provided. In this regard, the present embodiments may have different forms and should not be construed as being limited to the descriptions set forth herein. Accordingly, one or more embodiments are merely described in more detail herein, by referring to the drawings, to explain aspects of the present description.

In the present specification, “including A or B”, “A and/or B”, etc., represents A or B, or A and B.

As used herein, the term “and/or” includes any and all combinations of one or more of the associated listed items. Throughout the disclosure, the expression “at least one of a, b or c” indicates only a, only b, only c, both (e.g., simultaneously) a and b, both (e.g., simultaneously) a and c, both (e.g., simultaneously) b and c, all of a, b, and c, or variations thereof.

As the disclosure allows for one or more suitable changes and numerous embodiments, certain embodiments will be illustrated in the drawings and described in the written description. Effects and features of the disclosure, and methods for achieving them will be clarified with reference to one or more embodiments described herein in more detail with reference to the drawings. However, the disclosure is not limited to the following embodiments and may be embodied in one or more suitable forms.

Hereinafter, embodiments will be described in more detail with reference to the accompanying drawings, wherein like reference numerals refer to like elements throughout, and duplicative descriptions thereof may not be provided and a repeated description thereof is not provided.

While such terms as “first” and “second” may be used to describe one or more suitable elements, such elements must not be limited to the above terms. The above terms are used to distinguish one element from another.

The singular forms “a,” “an,” and “the” as used herein are intended to include the plural forms as well unless the context clearly indicates otherwise. In the present disclosure, it will be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having”, or other similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

It will be further understood that, if (e.g., when) a layer, region, or element is referred to as being “on” another layer, region, or element, it can be directly or indirectly on the other layer, region, or element. For example, for example, intervening layers, regions, or elements may be present.

Sizes of elements in the drawings may be exaggerated or reduced for convenience of explanation. As an example, the size and thickness of each element shown in the drawings are arbitrarily represented for convenience of description, and thus, the disclosure is not necessarily limited thereto.

In the case where a certain embodiment may be implemented differently, a specific process order may be performed in the order different from the described order. As an example, two processes successively described may be concurrently (e.g., simultaneously) performed substantially and performed in the opposite order.

In the present specification, “A and/or B” refers to A or B, or A and B. In the present specification, “at least one of A and B” refers to A or B, or A and B.

It will be understood that if (e.g., when) a layer, region, or element is referred to as being “connected” to another layer, region, or element, it may be “directly connected” to the other layer, region, or element or may be “indirectly connected” to the other layer, region, or element with another layer, region, or element located therebetween. For example, it will be understood that if (e.g., when) a layer, region, or element is referred to as being “electrically connected” to another layer, region, or element, it may be “directly electrically connected” to the other layer, region, or element or may be “indirectly electrically connected” to the other layer, region, or element with another layer, region, or element interposed therebetween.

The x-axis, the y-axis and the z-axis are not limited to three axes of the rectangular coordinate system, and may be interpreted in a broader sense. For example, the x-axis, the y-axis, and the z-axis may be normal (e.g., perpendicular) to one another, or may represent different orientations that are not normal (e.g., perpendicular) to one another.

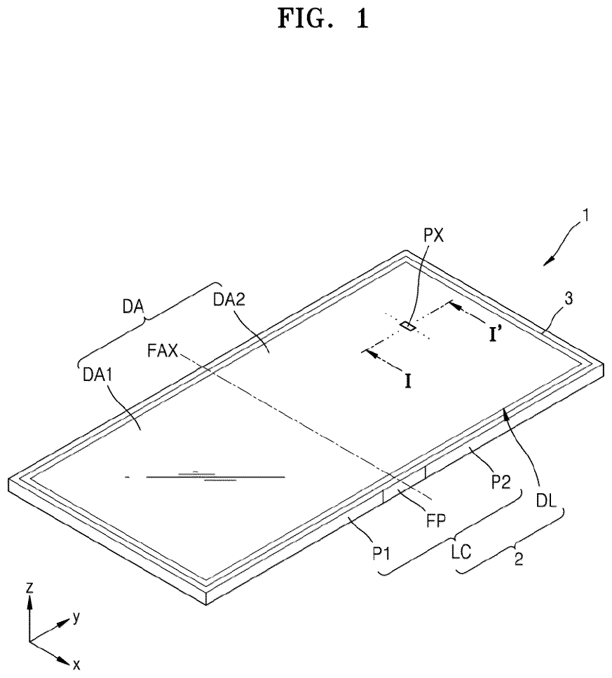

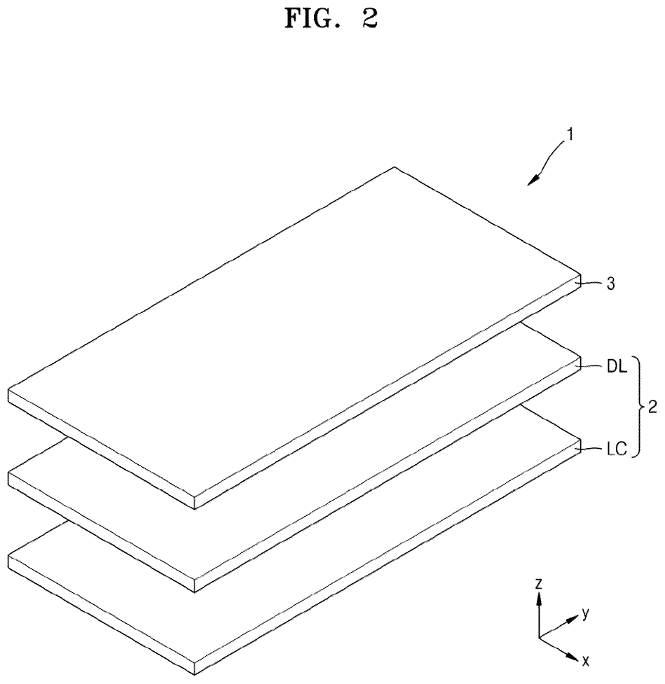

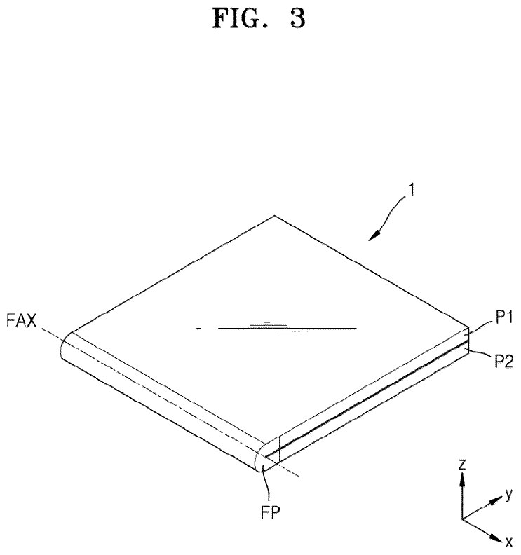

FIG. 1 is a schematic cross-sectional view of an electronic device 1 according to one or more embodiments. FIG. 2 is a schematic exploded cross-sectional view of the electronic device 1 according to one or more embodiments. FIG. 3 is a schematic cross-sectional view of the electronic device 1 according to one or more embodiments. FIG. 1 shows the electronic device 1 in an unfolded state, and FIG. 3 shows the electronic device 1 in a folded state.

Referring to FIGS. 1 to 3, the electronic device 1 may include a display device 2 and a cover window 3. The display device 2 may include a lower cover LC and a display layer DL. The display layer DL may be arranged on the lower cover LC, and the cover window 3 may be arranged on the display layer DL.

The lower cover LC may include a first portion P1 and a second portion P2 supporting the display layer DL. The lower cover LC may be folded around a folding axis FAX defined between the first portion P1 and the second portion P2. In one or more embodiments, the lower cover LC may further include a folding portion FP, and the folding portion FP may be arranged between the first portion P1 and the second portion P2.

The display layer DL may include a display area DA. The display layer DL may be configured to display images by using an array of a plurality of pixels PX arranged in the display area DA. Each of the pixels PX may be defined as an emission area from which light is emitted by a light-emitting element electrically connected to a pixel circuit. In one or more embodiments, each pixel PX may be configured to emit red, green, or blue light. In one or more embodiments, each pixel PX may be configured to emit red, green, blue, or white light.

The light-emitting element of the display layer DL may include an organic light-emitting diode, an inorganic light-emitting diode, a micro light-emitting diode, and/or a quantum-dot light-emitting diode. Hereinafter, for convenience of description, although a case where the light-emitting element of the display layer DL includes an organic light-emitting diode is mainly described, content (e.g., amount) described in more detail is not limited thereto and may be equally applicable to a case of including a different type (kind) of light-emitting element.

The display area DA may include a first display area DA1 and a second display area DA2, wherein the first display area DA1 and the second display area DA2 are respectively arranged on two opposite sides around the folding axis FAX crossing the display area DA. For example, the folding axis FAX may be between the first display area DA1 and the second display area DA2. The first display area DA1 may overlap the first portion P1 of the lower cover LC. The second display area DA2 may overlap the second portion P2 of the lower cover LC. The display layer DL may be configured to display a first image and a second image by using light emitted from the plurality of pixels PX arranged in the first display area DA1 and the second display area DA2. In one or more embodiments, the first image and the second image may be portions of one of images displayed in the display area DA of the display layer DL. In another embodiment, the display layer DL may be configured to display the first image and the second image which are independent of each other.

The electronic device 1 may be folded around the folding axis FAX. When the electronic device 1 is folded, the display device 2, the lower cover LC, the display layer DL, and the cover window 3 may be also folded. When the electronic device 1 is folded, the first display area DA1 and the second display area DA2 of the display layer DL may face each other.

Although it is shown in FIGS. 1 and 3 that the folding axis FAX extends in an x axis direction, the disclosure is not limited thereto. In one or more embodiments, the folding axis FAX may extend in a y axis direction crossing the x axis direction. In one or more embodiments, the folding axis FAX may extend in a direction crossing the x axis direction and the y axis direction on an xy-plane.

In addition, although it is shown in FIGS. 1 and 3 that the folding axis FAX is one, the disclosure is not limited thereto. In one or more embodiments, the display layer DL may be folded multiple times around a plurality of folding axes FAX crossing the display area DA.

The cover window 3 may be arranged on the display layer DL and may cover the display layer DL. The cover window 3 may be folded or warped according to external force without crack occurrence. When the display layer DL is folded around the folding axis FAX, the cover window 3 may be folded together.

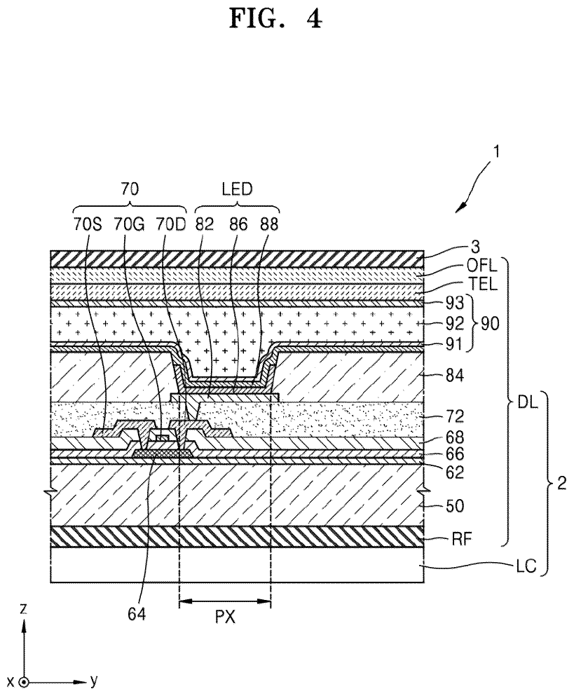

FIG. 4 is a schematic cross-sectional view of a portion of the electronic device 1 according to one or more embodiments. FIG. 4 may correspond to a cross-sectional view of the electronic device 1, taken along the line I-I′ of FIG. 1.

Referring to FIG. 4, the electronic device 1 may include the display device 2 and the cover window 3 arranged on the display device 2. The display device 2 may include the lower cover LC and the display layer DL arranged on the lower cover LC.

The display layer DL may include, for example, a light-emitting diode LED as a light-emitting element. However, the disclosure is not necessarily limited thereto and the display layer DL may include, as a light-emitting element, a different light-emitting device such as a liquid crystal display and an electrophoretic display.

A reinforcement substrate RF may be arranged on the lower surface of a first substrate 50. The reinforcement substrate RF is a substrate for supporting the electronic device 1 from the first substrate 50 through the display layer DL to the cover window 3. The reinforcement substrate RF may include a reinforcing body and a reinforcing layer. The reinforcement substrate RF may prevent or reduce crease from occurring in a folding region of the display layer DL due to repeated folding. In one or more embodiments, the reinforcement substrate RF may not be provided.

A buffer layer 62 may be arranged on the first substrate 50. The buffer layer 62 may include an inorganic material such as silicon oxide (SiO_{Y}, e.g., SiO₂), silicon nitride (SiN_{X}), and/or silicon oxynitride (SiON). The buffer layer 62 may increase the flatness of the upper surface of the first substrate 50 or prevent or reduce or reduce impurities from penetrating an active layer 64 of a thin-film transistor 70. In one or more embodiments, the buffer layer 62 may not be provided.

The thin-film transistor 70 may be arranged on the first substrate 50, and the thin-film transistor 70 may be electrically connected to a pixel electrode 82. The thin-film transistor 70 may include the active layer 64, a gate electrode 70G, a source electrode 70S, and a drain electrode 70D, wherein the active layer 64 includes a semiconductor material such as amorphous silicon, polycrystalline silicon, an oxide semiconductor, or an organic semiconductor, the gate electrode 70G is insulated from the active layer 64, and each of the source electrode 70S and the drain electrode 70D is electrically connected to the active layer 64. The gate electrode 70G may be arranged over the active layer 64, and the source electrode 70S and the drain electrode 70D may be electrically communicated with each other according to a signal applied to the gate electrode 70G. The gate electrode 70G may include at least one of aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), or copper (Cu), and include a single layer or a multi-layer by taking into account adhesion with adjacent layers, surface flatness of stacked layers, workability, and/or the like.

For insulation between the active layer 64 and the gate electrode 70G, a first insulating layer 66 may be arranged between the active layer 64 and the gate electrode 70G. The first insulating layer 66 may include an inorganic material such as silicon oxide (SiO₂), silicon nitride (SiN_{X}), and/or silicon oxynitride (SiON). A second insulating layer 68 may be arranged on the gate electrode 70G, and the source electrode 70S and the drain electrode 70D may be arranged on the second insulating layer 68. The source electrode 70S and the drain electrode 70D are respectively electrically connected to the active layer 64 through contact holes formed in the first insulating layer 66. The second insulating layer 68 may include an inorganic material such as silicon oxide (SiO_{Y}, e.g., SiO), silicon nitride (SiN_{X}), and/or silicon oxynitride (SiON).

A third insulating layer 72 may be arranged on the thin-film transistor 70, wherein the third insulating layer 72 covers the thin-film transistor 70. The third insulating layer 72 may have a flat upper surface such that the pixel electrode 82 is formed flat. The third insulating layer 72 may include an organic material such as acryl, benzocyclobutene (BCB), polyimide (PI), or hexamethyldisiloxane (HMDSO). Although it is shown in FIG. 4 that the third insulating layer 72 is a single layer, the third insulating layer 72 may be a multi-layer.

The third insulating layer 72 may include a via hole exposing one of the source electrode 70S and the drain electrode 70D of the thin-film transistor 70. The pixel electrode 82 may be electrically connected to the thin-film transistor 70 by being in contact with one of the source electrode 70S and the drain electrode 70D through the via hole. As an example, it is shown in FIG. 4 that the pixel electrode 82 is connected to the drain electrode 70D.

The light-emitting diode LED may be arranged on the third insulating layer 72, wherein the light-emitting diode LED includes the pixel electrode 82, an intermediate layer 86 arranged on the pixel electrode 82 and including an emission layer, and an opposite electrode 88.

In one or more embodiments, the pixel electrode 82 may include a reflective electrode. In the case where the pixel electrode 82 includes a reflective electrode, the pixel electrode 82 may include a reflective layer and a transparent conductive layer arranged on and/or under the reflective layer, the reflective layer including silver (Ag), magnesium (Mg), aluminum (Al), platinum (Pt), palladium (Pd), gold (Au), nickel (Ni), neodymium (Nd), iridium (Ir), chrome (Cr), or a compound thereof. The transparent conductive layer may include at least one selected from among indium tin oxide (ITO), indium zinc oxide (IZO), zinc oxide (ZnO), indium oxide (In₂O₃), indium gallium oxide (IGO), and aluminum-zinc oxide (AZO). However, the disclosure is not limited thereto and the pixel electrode 82 may include one or more suitable materials, and the structure thereof may be a single layer or a multi-layer and be variously modified.

A pixel-defining layer 84 may be arranged on the third insulating layer 72, wherein the pixel-defining layer 84 covers edge regions of the pixel electrode 82. The pixel-defining layer 84 includes an opening exposing a portion of the pixel electrode 82 and may define a pixel. The pixel-defining layer 84 may include an organic material such as PI or HMDSO. The pixel-defining layer 84 may include a single layer or a plurality of layers.

The intermediate layer 86 may be arranged on the central portion of the pixel electrode 82 exposed by the pixel-defining layer 84. The intermediate layer 86 may include an emission layer (EML), and in addition, may further include functional layers such as a hole injection layer (HIL), a hole transport layer (HTL), an electron transport layer (ETL), and/or an electron injection layer (EIL).

The structure of the intermediate layer 86 is not necessarily limited thereto and may have one or more suitable structures. In addition, the intermediate layer 86 may include an integral layer over a plurality of pixel electrodes 82, or include a layer patterned to correspond to each of the plurality of pixel electrodes 82.

The opposite electrode 88 may be arranged on the intermediate layer 86. Unlike the pixel electrode 82, the opposite electrode 88 may be integrally formed over the plurality of pixels.

The opposite electrode 88 may include a (semi) transparent electrode. In the case where the opposite electrode 88 includes a (semi) transparent electrode, the opposite electrode 88 may include a thin-film including at least one selected from among silver (Ag), aluminum (Al), magnesium (Mg), lithium (Li), calcium (Ca), copper (Cu), lithium/calcium fluoride (LiF/Ca), lithium/aluminum fluoride (LiF/Al), magnesium-silver alloy (MgAg), and calcium-silver alloy (CaAg), and may include a thin film having a thickness of several nm to several tens of nm. The construction and material of the opposite electrode 88 are not limited thereto and may be variously or suitably modified.

A thin-film encapsulation layer 90 may be arranged on the opposite electrode 88. The thin-film encapsulation layer 90 encapsulates the light-emitting diode LED such that the light-emitting diode LED is not exposed to external air or foreign substance. Because the thin-film encapsulation layer 90 has a very thin thickness, the thin-film encapsulation layer 90 may be used as a sealing means of a flexible display device that is bendable or foldable.

The thin-film encapsulation layer 90 may include a first inorganic encapsulation layer 91, an organic encapsulation layer 92, and a second inorganic encapsulation layer 93 sequentially arranged on the opposite electrode 88. The first inorganic encapsulation layer 91 may include silicon oxide (SiO_{Y}, e.g., SiO), silicon nitride (SiN_{X}), and/or silicon oxynitride (SiON). Because the first inorganic encapsulation layer 91 is formed along a structure thereunder, the upper surface of the first inorganic encapsulation layer 91 may not be flat as shown in FIG. 3. The organic encapsulation layer 92 covers the first inorganic encapsulation layer 91 and may form a flat upper surface. The organic encapsulation layer 92 may include at least one material selected from among polyethylene terephthalate, polyethylene naphthalate, polycarbonate, polyimide, polyethylene sulfonate, polyoxymethylene, and polyarylate, hexamethyldisiloxane. The second inorganic encapsulation layer 93 may cover the organic encapsulation layer 92 and may include silicon oxide (SiO_{Y}, e.g., SiO), silicon nitride (SiNₓ), and/or silicon oxynitride (SiON). Although it is shown as an example in FIG. 4 that the thin-film encapsulation layer 90 includes one organic encapsulation layer 92, the thin-film encapsulation layer 90 may have a structure in which a plurality of organic encapsulation layers and inorganic encapsulation layers are alternately stacked.

A touch electrode layer TEL including touch electrodes may be arranged on the thin-film encapsulation layer 90, and an optical functional layer OFL may be arranged on the touch electrode layer TEL. The touch electrode layer TEL may obtain coordinate information corresponding to an external input, for example, a touch event. The optical functional layer OFL may reduce the reflectivity of light (external light) incident toward the electronic device 1 from the outside, and improve the color purity of light emitted from the electronic device 1.

In one or more embodiments, the optical functional layer OFL may include a phase retarder and/or a polarizer. The phase retarder may include a film-type (kind) retarder or a liquid crystal-type (kind) retarder. The phase retarder may include a λ/2 phase retarder and/or a λ/4 phase retarder. The polarizer may include a film-type (kind) polarizer or a liquid crystal coated-type (kind) polarizer. The film-type (kind) polarizer may include a stretchable synthetic resin film, and the liquid crystal coated-type (kind) polarizer may include liquid crystals arranged in a set or predetermined arrangement. Each of the phase retarder and the polarizer may further include a protective film.

In one or more embodiments, the optical functional layer OFL may include a destructive interference structure. The destructive interference structure may include a first reflection layer and a second reflection layer respectively arranged on different layers. First-reflected light and second-reflected light respectively reflected by the first reflection layer and the second reflection layer may interfere (e.g., destructively interfere) and thus the reflectivity of external light may be reduced.

In one or more embodiments, an adhesive member may be arranged between the touch electrode layer TEL and the optical functional layer OFL. For the adhesive member, a general adhesive suitable in the art may be employed without limitation. As an example, the adhesive member may include a pressure sensitive adhesive (PSA).

The cover window 3 may be arranged on the display layer DL. The cover window 3 may be adhered to the display layer DL by the adhesive member. The adhesive member may include, for example, a PSA.

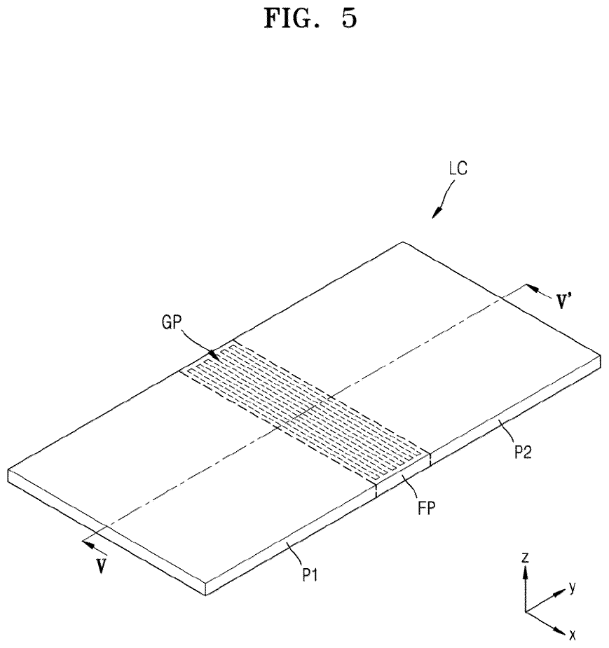

FIG. 5 is a perspective view of the lower cover LC according to one or more embodiments.

Referring to FIG. 5, the lower cover LC may include the first portion P1 and the second portion P2 to correspond to the electronic device 1. The lower cover LC may include the folding portion FP arranged between the first portion P1 and the second portion P2. The lower cover LC may be folded in the folding portion FP. As an example, the lower cover LC may be folded in the folding portion FP around the folding axis FAX (see FIG. 1). The lower cover LC may include glass and further include a glass pattern GP arranged in the folding portion FP. Terms such as the folding region and folding area used in the present specification may denote the folding portion FP.

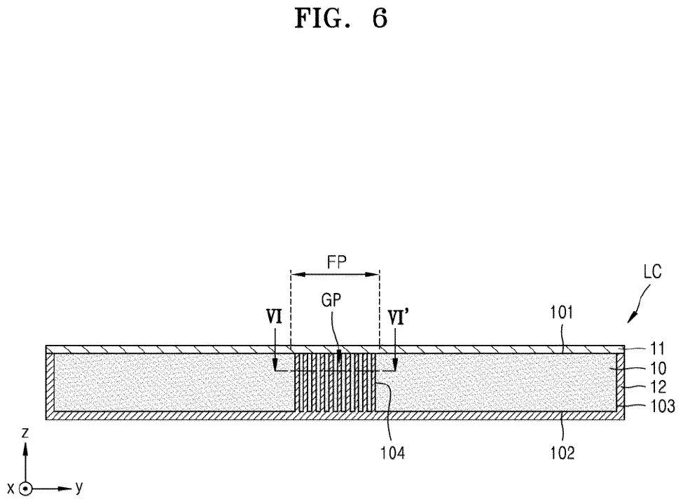

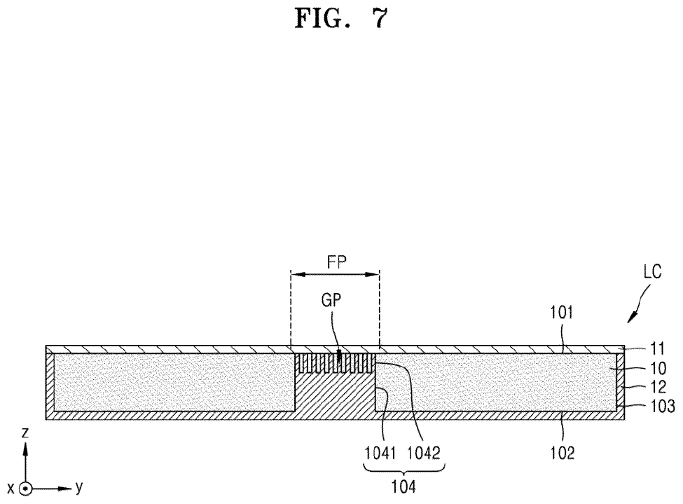

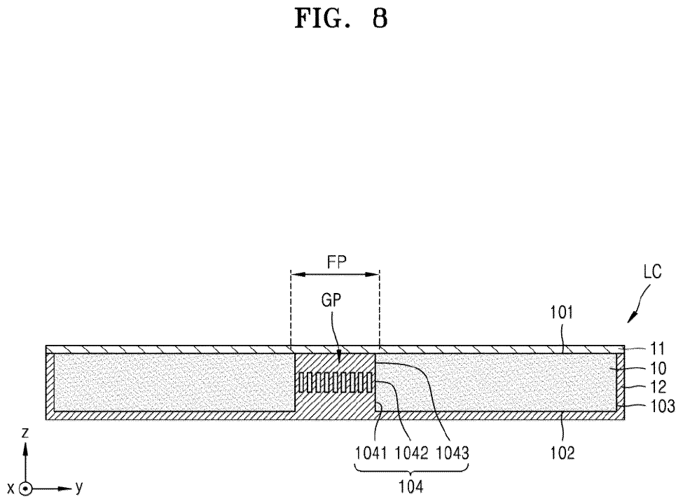

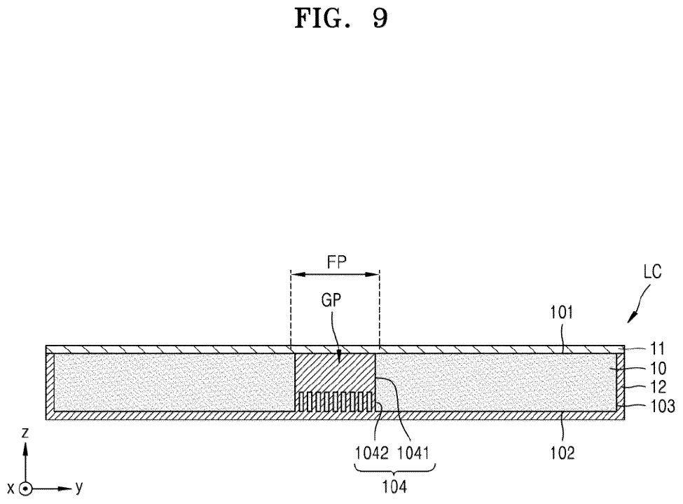

FIG. 6 is a cross-sectional view of the lower cover LC according to one or more embodiments. FIG. 7 is a cross-sectional view of the lower cover LC according to one or more embodiments. FIG. 8 is a cross-sectional view of the lower cover LC according to one or more embodiments. FIG. 9 is a cross-sectional view of the lower cover LC according to one or more embodiments. FIGS. 6 to 9 may correspond to cross-sectional views of the lower cover LC, taken along the line V-V′ of FIG. 5.

Referring to FIGS. 6 to 9, the lower cover LC may include a glass layer 10, a first resin layer 11, and a second resin layer 12.

The glass layer 10 may have a first surface 101 and a second surface 102. The second surface 102 may be an opposite surface of the first surface 101. For example, the second surface 102 may be opposite to the first surface 101. In one or more embodiments, the first surface 101 of the glass layer 10 may be the upper surface of the glass layer 10, and the second surface 102 of the glass layer 10 may be the lower surface of the glass layer 10. The first surface 101 of the glass layer 10 may face a z axis direction. The second surface 102 of the glass layer 10 may face an opposite direction of the z axis direction. In the present specification, a more detailed description is made on the assumption that the first surface 101 is the upper surface and the second surface 102 is the lower surface. In this case, an expression such as “arranged on the first surface 101” may be also understood as “arranged on (or over) the glass layer 10”, and an expression such as “arranged on the second surface 102” may be also understood as “arranged under (or below) the glass layer 10”. However, the disclosure is not necessarily limited to this orientation. For example, the glass layer 10 has two surfaces: a first surface 101 and a second surface 102, which are opposite each other. In some embodiments, the first surface 101 is the upper surface, and the second surface 102 is the lower surface. The first surface faces the z-axis direction, while the second surface faces the opposite direction. The description assumes this orientation, but the disclosure is not limited to it. Terms like “arranged on the first surface 101” can be understood as “arranged on or over the glass layer 10,” and “arranged on the second surface 102” can be understood as “arranged under or below the glass layer 10.”

The glass layer 10 may include a third surface 103 extending between the first surface 101 and the second surface 102. In one or more embodiments, the third surface 103 of the glass layer 10 may be a lateral surface of the glass layer 10. The third surface 103 may extend in the x axis direction or y axis direction. The third surface 103 shown in FIGS. 6 to 9 may be a surface extending in the x axis direction. In one or more embodiments, the third surface 103 may extend in the x axis direction or y axis direction and define the circumference of the glass layer 10.

The first resin layer 11 may be arranged on the first surface 101 of the glass layer 10. The first resin layer 11 may cover the first surface 101 of the glass layer 10. The second resin layer 12 may be arranged on the second surface 102 and the third surface 103 of the glass layer 10. The second resin layer 12 may cover the second surface 102 and the third surface 103 of the glass layer 10. The first resin layer 11 and the second resin layer 12 may be in contact with each other near the edge in which the first surface 101 and the third surface 103 of the glass layer 10 meet each other.

The glass layer 10 may include the glass pattern GP arranged in the folding portion FP. In one or more embodiments, the glass pattern GP may take the form of or include a groove. As an example, the glass pattern GP may have a groove 104 defined in the glass layer 10 in the folding portion FP. In one or more embodiments, a portion of the second resin layer 12 may be arranged inside the groove 104. In one or more embodiments, the groove 104 may be defined to pass through the glass layer 10. For example, the groove 104 may be a penetration hole. In this case, a portion of the second resin layer 12 arranged inside the groove 104 may be in contact with the first resin layer 11. For example, the first resin layer 11 and the second resin layer 12 may be in contact with each other in a region overlapping the groove 104.

Because one or more embodiments shown in FIGS. 6 to 9 are different in the shape of the groove 104 of the glass layer 10, the difference is mainly described in more detail herein.

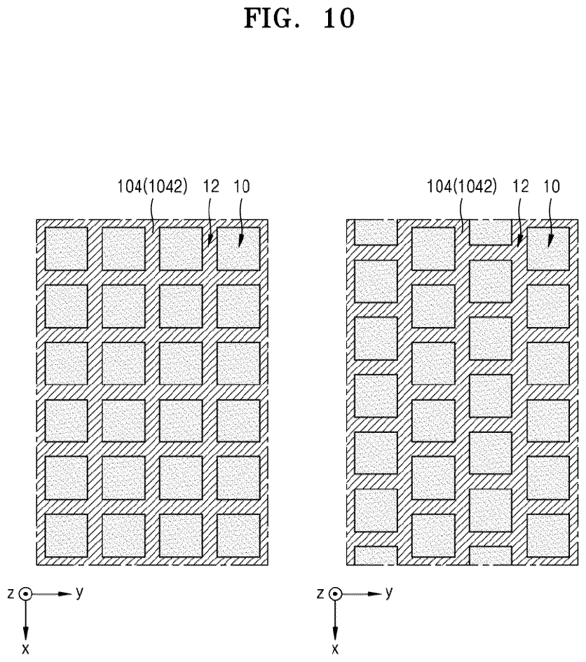

Referring to FIG. 6, the groove 104 may extend in the z axis direction and have a set or preset shape in the z axis direction. A planar shape of the groove 104 is described in more detail with reference to FIGS. 10 to 12. As described above, the groove 104 may be defined to pass through the glass layer 10.

Referring to FIG. 7, the groove 104 may have a first opening 1041 and a second opening 1042. The first opening 1041 may be integrally defined inside the folding portion FP. The second opening 1042 may have a plurality of portions. The first opening 1041 may be open toward the second surface 102 of the glass layer 10. The second opening 1042 may be open toward the first surface 101 of the glass layer 10. The second opening 1042 may be arranged on the first opening 1041. The first opening 1041 and the second opening 1042 may be connected to each other. A portion of the second resin layer 12 may be arranged inside the first opening 1041, and another portion of the second resin layer 12 may be arranged inside the second opening 1042.

Referring to FIG. 8, the groove 104 may have the first opening 1041, the second opening 1042, and a third opening 1043. The first opening 1041 may be integrally defined inside the folding portion FP. The second opening 1042 may have a plurality of portions. The third opening 1043 may be integrally defined inside the folding portion FP. The shape of the first opening 1041 and the shape of the third opening 1043 may be the same. The first opening 1041 may be open toward the second surface 102 of the glass layer 10. The third opening 1043 may be open toward the first surface 101 of the glass layer 10. The second opening 1042 may be arranged between the first opening 1041 and the third opening 1043 and may connect the first opening 1041 to the third opening 1043. A portion of the second resin layer 12 may be arranged inside the first opening 1041, another portion may be arranged inside the second opening 1042, and another portion may be arranged inside the third opening 1043.

Referring to FIG. 9, the groove 104 may have a first opening 1041 and a second opening 1042. The first opening 1041 may be integrally defined inside the folding portion FP. The second opening 1042 may have a plurality of portions. The first opening 1041 may be open toward the first surface 101 of the glass layer 10. The second opening 1042 may be open toward the second surface 102 of the glass layer 10. The second opening 1042 may be arranged under the first opening 1041. The first opening 1041 and the second opening 1042 may be connected to each other. A portion of the second resin layer 12 may be arranged inside the first opening 1041, and another portion of the second resin layer 12 may be arranged inside the second opening 1042.

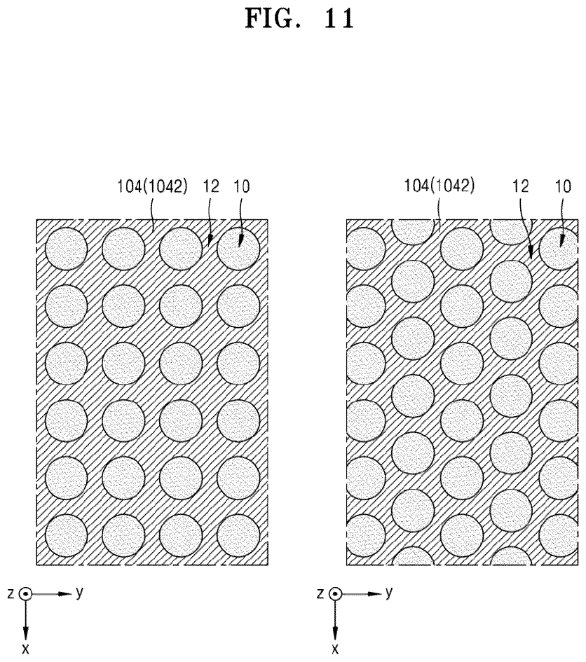

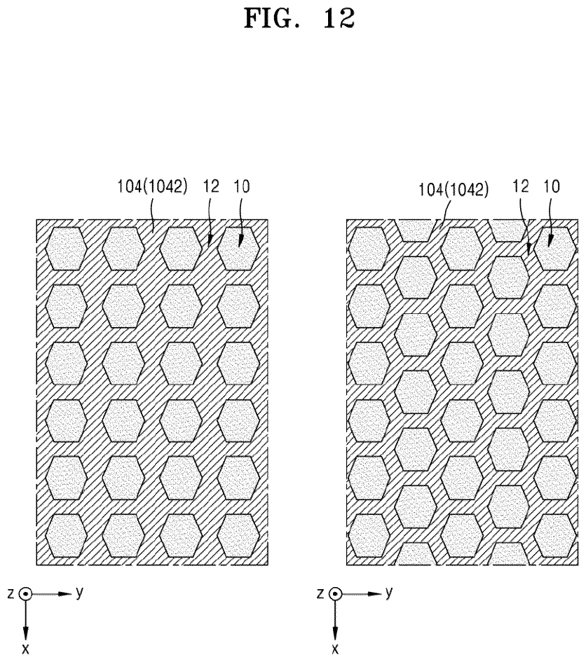

FIG. 10 shows excerpted plan views of a portion of the lower cover LC according to one or more embodiments. FIG. 11 shows excerpted plan views of a portion of the lower cover LC according to one or more embodiments. FIG. 12 shows excerpted plan views of a portion of the lower cover LC according to one or more embodiments. For convenience of illustration and description, FIGS. 10 to 12 show two examples of a plan view of a portion of the lower cover LC.

Referring to FIGS. 10 to 12, the groove 104 may be defined in the glass layer 10, and a portion of the second resin layer 12 may be arranged inside the groove 104 of the glass layer 10. The first opening 1041 and the third opening 1043 may be integrally formed, and the second opening 1042 may include a plurality of portions. As an example, the second opening 1042 may include a plurality of portions extending approximately or substantially in the x axis direction and/or the y axis direction. At least some of the plurality of portions of the second opening 1042 may be connected to each other. For example, the second opening 1042 may have a roughly mesh or net shape. In a region in which the second opening 1042 is defined, the glass layer 10 may have a plurality of island shapes. To describe one or more suitable shapes that the second opening 1042 of the groove 104 may have in particular, FIGS. 10 to 12 excerpt a portion of the groove 104 in which the second opening 1042 in particular is located. Accordingly, FIGS. 10 to 12 may correspond to plan views of the lower cover LC, taken along the line VI-VI′ of FIG. 6, and correspond to an excerpted plan view of a region adjacent to the second opening 1042 of FIGS. 7 to 9. Hereinafter, although the second opening 1042 is mainly described, the following characteristics are applicable to the groove 104 of FIG. 6. For example, the groove 104 in the glass layer 10 contains a portion of the second resin layer 12. The first opening 1041 and the third opening 1043 are integrally formed, while the second opening 1042 is composed of multiple portions, potentially extending in the x and/or y axis directions. These portions may be interconnected, forming a mesh or net shape. In the region with the second opening 1042, the glass layer 10 may have multiple island shapes. FIGS. 10 to 12 illustrate various shapes of the second opening 1042 within the groove 104, corresponding to plan views of the lower cover LC and regions adjacent to the second opening 1042. The described characteristics also apply to the groove 104 in FIG. 6.

Referring to FIG. 10, the second opening 1042 of the glass layer 10 may have a mesh (or net) shape including roughly square holes. The glass layer 10 may be arranged inside the square holes of the mesh (or net). Accordingly, the glass layer 10 may have roughly (e.g., substantially) square-shaped islands.

Referring to the left of FIG. 10, square holes of the mesh (or net) of the second opening 1042 may be aligned along the x axis and/or y axis. For example, square islands of the glass layer 10 may be aligned along the x axis and/or y axis.

Referring to the right of FIG. 10, square holes of the mesh (or net) of the second opening 1042 may be aligned (arranged with one another) along the x axis and may alternate (switch positions) along the y axis. For example, the square islands of the glass layer 10 may be aligned along the x axis and may alternate along the y axis. In another embodiment, square holes of the second opening 1042 (or square islands of the glass layer 10) may be aligned along the y axis and may alternate along the x axis. For example, the square holes of the second opening 1042 and the square islands of the glass layer 10 may be aligned and alternate along either the x-axis or the y-axis.

Referring to FIG. 11, the second opening 1042 of the glass layer 10 may have a mesh (or net) shape including roughly circular holes. The glass layer 10 may be arranged inside the mesh (or net) circular holes. Accordingly, the glass layer 10 may have roughly circular islands.

Referring to the left of FIG. 11, circular holes of the mesh (or net) of the second opening 1042 may be aligned in the x axis and/or y axis. For example, circular islands of the glass layer 10 may be aligned in the x axis and/or y axis.

Referring to the right of FIG. 11, circular holes of the mesh (or net) of the second opening 1042 may be aligned in the x axis and may alternate in the y axis. For example, circular islands of the glass layer 10 may be aligned in the x axis and may alternate in the y axis. In another embodiment, circular holes of the mesh (or net) of the second opening 1042 (or circular islands of the glass layer 10) may be aligned in the y axis and may alternate in the x axis. The circular holes of the mesh (or net) of the second opening 1042 (or the circular islands of the glass layer 10) may be arranged closer to each other and in greater numbers within the same (e.g., substantially the same) area in one or more embodiments illustrated on the right side of FIG. 11 than in one or more embodiments illustrated on the left side of FIG. 11. For example, the circular holes of the mesh (or net) of the second opening 1042 and the circular islands of the glass layer 10 may be aligned and alternate along either the x-axis or the y-axis. The right side of FIG. 11 shows these circular holes or islands arranged closer together and in greater numbers compared to the left side of FIG. 11.

Referring to FIG. 12, the second opening 1042 of the glass layer 10 may have a mesh (or net) shape including roughly hexagonal holes. The glass layer 10 may be arranged inside the hexagonal holes of the mesh (or net). Accordingly, the glass layer 10 may have roughly hexagonal islands.

Referring to the left of FIG. 12, hexagonal holes of the mesh (or net) of the second opening 1042 may be aligned in the x axis and/or y axis. For example, hexagonal islands of the glass layer 10 may be aligned in the x axis and/or y axis.

Referring to the right of FIG. 12, hexagonal holes of the mesh (or net) of the second opening 1042 may be aligned in the x axis and may alternate in the y axis. For example, hexagonal islands of the glass layer 10 may be aligned in the x axis and may alternate in the y axis. In another, hexagonal holes of the mesh (or net) of the second opening 1042 (or hexagonal islands of the glass layer 10) may be aligned in the y axis and may alternate in the x axis. The hexagonal holes of the mesh (or net) of the second opening 1042 (or the hexagonal islands of the glass layer 10) may be arranged closer to each other and in greater numbers within the same (e.g., substantially the same) area in one or more embodiments illustrated on the right side of FIG. 12 than in one or more embodiments illustrated on the left side of FIG. 12. For example, the hexagonal holes of the second opening 1042 and the hexagonal islands of the glass layer 10 may be aligned and alternate along either the x-axis or the y-axis. The right side of FIG. 12 shows these hexagonal holes or islands arranged closer together and in greater numbers compared to the left side of FIG. 12.

In the above, the structure shown in FIGS. 10 to 12 has been described by utilizing an expression of “mesh (or net) of the second opening 1042 and islands of the glass layer 10”. However, in another viewpoint, the above-described structures may be understood as having a valley formed in the glass layer 10 extending approximately or substantially in the x axis and/or the y axis, the second opening 1042 corresponding to the valley, and the second resin layer 12 filling the valley. For example, the structures shown in FIGS. 10 to 12 may be described as having a “mesh (or net) of the second opening 1042 and islands of the glass layer 10.” Alternatively, these structures may be understood as having a valley formed in the glass layer 10, extending along the x and/or y axis, with the second opening 1042 corresponding to the valley and the second resin layer 12 filling the valley.

It will be apparent to those of ordinary skill in the art that the scope of the disclosure is not necessarily limited to the shapes and arrangements shown in FIGS. 10 to 12, and that one or more suitable shapes, sizes, and arrangements may be adopted and/or combined.

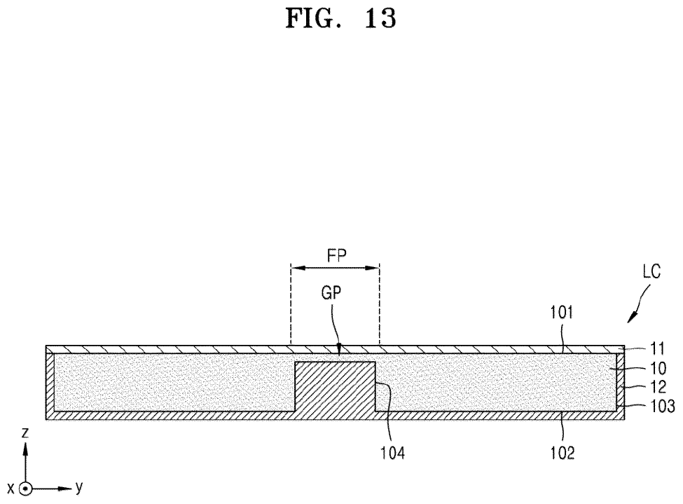

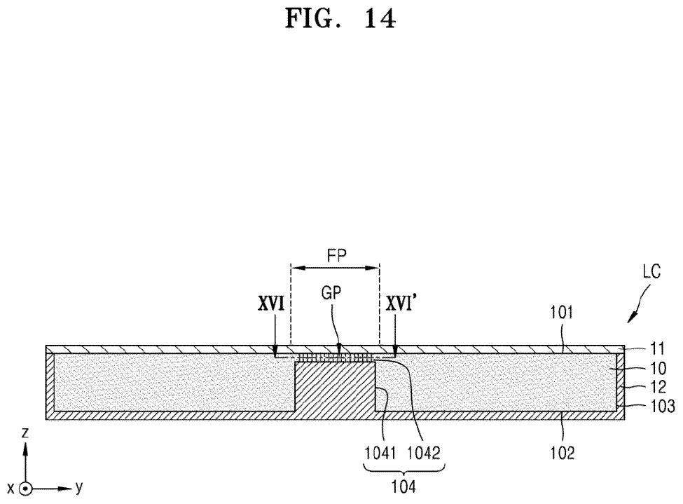

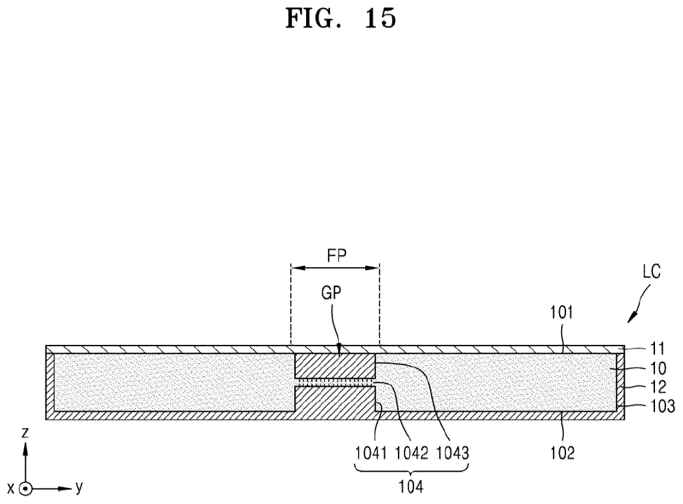

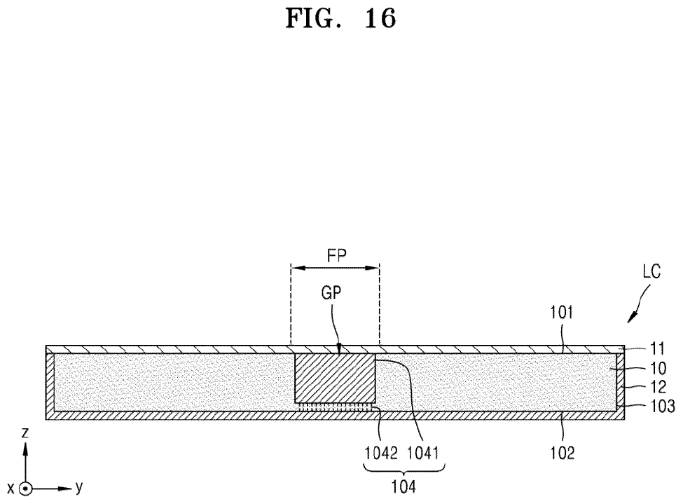

FIG. 13 is a cross-sectional view of the lower cover LC according to one or more embodiments. FIG. 14 is a cross-sectional view of the lower cover LC according to one or more embodiments. FIG. 15 is a cross-sectional view of the lower cover LC according to one or more embodiments. FIG. 16 is a cross-sectional view of the lower cover LC according to one or more embodiments. FIGS. 13 to 16 may correspond to cross-sectional views of the lower cover LC, taken along the line V-V′ of FIG. 5.

Among characteristics of embodiments shown in FIGS. 13 to 16, characteristics other than characteristics described in more detail with reference to FIGS. 13 to 16, some characteristics may be the same as those described with reference to FIGS. 6 to 9.

Referring to FIG. 13, the groove 104 may extend in the z axis direction and be integrally formed. The groove 104 may have a set or preset shape in the z axis direction. The groove 104 may not pass through the glass layer 10. For example, the groove 104 may be a blind hole.

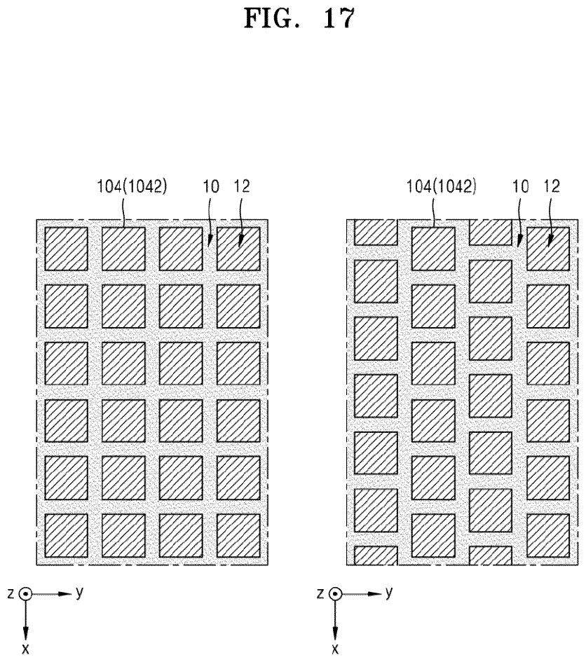

Referring to FIG. 14, the groove 104 may have the first opening 1041 and the second opening 1042. The first opening 1041 may be integrally defined inside the folding portion FP. The second opening 1042 may be provided in plurality. The first opening 1041 may be open toward the second surface 102 of the glass layer 10. The plurality of second openings 1042 may be open or may not be open toward the first surface 101 of the glass layer 10. The groove 104 may pass through the glass layer 10 entirely and may not pass through the glass layer 10. The plurality of second openings 1042 may be arranged on the first opening 1041. The first opening 1041 may be connected to the plurality of second openings 1042. A portion of the second resin layer 12 may be arranged inside the first opening 1041, and another portion of the second resin layer 12 may be arranged inside the plurality of second openings 1042. A planar shape of the plurality of second openings 1042 will be described in more detail with reference to FIGS. 17 to 19.

Referring to FIG. 15, the groove 104 may have the first opening 1041, the second opening 1042, and the third opening 1043. The first opening 1041 may be integrally defined inside the folding portion FP. The second opening 1042 may be provided in plurality. The third opening 1043 may be integrally defined inside the folding portion FP. The shape of the first opening 1041 and the shape of the third opening 1043 may be the same. The first opening 1041 may be open toward the second surface 102 of the glass layer 10. The third opening 1043 may be open toward the first surface 101 of the glass layer 10. The plurality of second openings 1042 may be arranged between the first opening 1041 and the third opening 1043 and may connect the first opening 1041 to the third opening 1043. A portion of the second resin layer 12 may be arranged inside the first opening 1041, another portion may be arranged inside the plurality of second opening 1042, and another portion may be arranged inside the third opening 1043.

Referring to FIG. 16, the groove 104 may have the first opening 1041 and the second opening 1042. The first opening 1041 may be integrally defined inside the folding portion FP. The second opening 1042 may be provided in plurality. The first opening 1041 may be open or may not be open toward the second surface 102 of the glass layer 10. The plurality of second openings 1042 may be open toward the first surface 101 of the glass layer 10. The groove 104 may pass through the glass layer 10 entirely and may not pass through the glass layer 10. The plurality of second openings 1042 may be arranged under the first opening 1041. The first opening 1041 may be connected to the plurality of second openings 1042. A portion of the second resin layer 12 may be arranged inside the first opening 1041, and another portion of the second resin layer 12 may be arranged inside the plurality of second openings 1042.

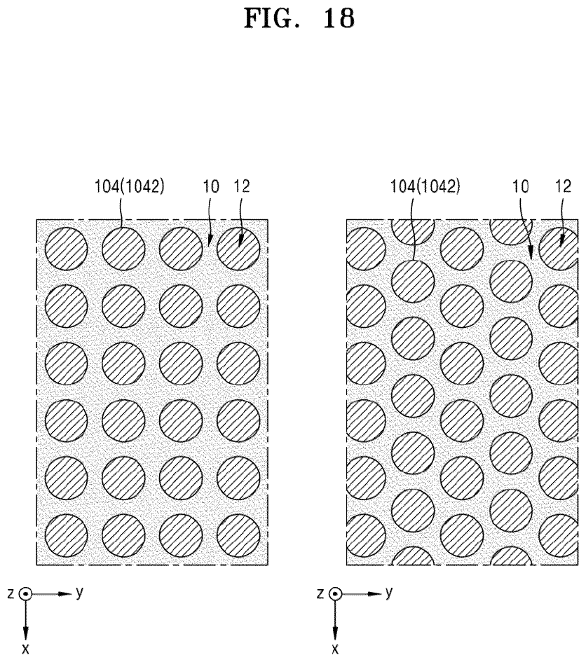

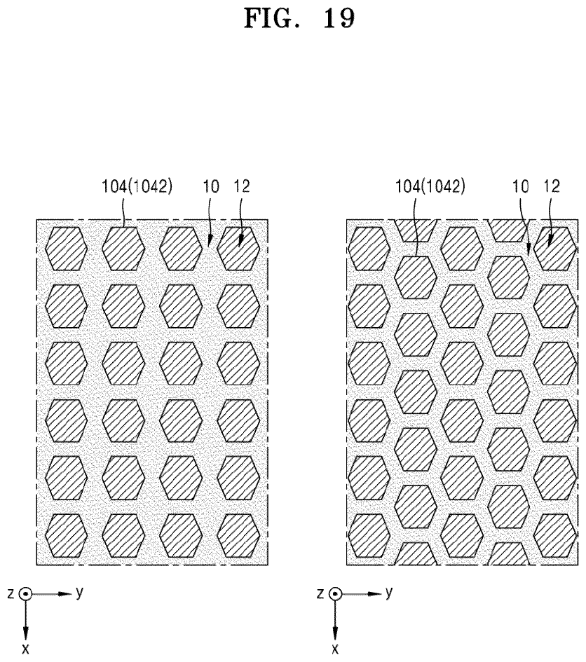

FIG. 17 shows excerpted plan views of a portion of the lower cover LC according to one or more embodiments. FIG. 18 shows excerpted plan views of a portion of the lower cover LC according to one or more embodiments. FIG. 19 shows excerpted plan views of a portion of the lower cover LC according to one or more embodiments. For convenience of illustration and description, FIGS. 10 to 12 show two examples of a plan view of a portion of the lower cover LC.

Referring to FIGS. 17 to 19, the groove 104 may be defined in the glass layer 10, and a portion of the second resin layer 12 may be arranged inside the groove 104 of the glass layer 10. The first opening 1041 and the third opening 1043 may be integrally provided, and the second opening 1042 may be provided in plurality. As an example, the plurality of second openings 1042 may be arranged apart from each other in the x axis and/or y axis. In a region in which the second opening 1042 is defined, the glass layer 10 may have a mesh or net shape. To describe one or more suitable shapes that the second opening 1042 of the groove 104 may have in particular, FIGS. 17 to 19 excerpt a portion in which the second opening 1042 is located. Accordingly, FIGS. 17 to 19 may correspond to plan views of the lower cover LC, taken along the line XIV-XIV′ of FIG. 14, and correspond to an excerpted plan view of a region adjacent to the second opening 1042 of FIGS. 15 and 16.

Referring to FIG. 17, the second opening 1042 of the glass layer 10 may be a square hole. The glass layer 10 may have a mesh (or net) shape including a plurality of square holes (that is, the second openings 1042). The second resin layer 12 may be arranged inside the square holes of the mesh (or net). For example, the second resin layer 12 may be arranged inside the plurality of second openings 1042. Because the shape of the second resin layer 12 may be the same as the shapes of the plurality of second openings 1042, the second resin layer 12 may include a plurality of square islands.

Referring to the left of FIG. 17, the square holes (that is, the second openings 1042) may be aligned along the x axis and/or y axis. For example, square islands of the second resin layer 12 may be aligned along the x axis and/or y axis.

Referring to the right of FIG. 17, the square holes (that is, the second openings 1042) may be aligned along the x axis and alternate along the y axis. For example, square islands of the second resin layer 12 may be aligned along the x axis and may alternate along the y axis. In another embodiment, the square holes (that is, the second holes 1042) or the square islands of the second resin layer 12 may be aligned along the y axis and may alternate along the x axis.

Referring to FIG. 18, the second opening 1042 of the glass layer 10 may be a circular hole. The glass layer 10 may have a mesh (or net) shape including a plurality of circular holes (that is, the second openings 1042). The second resin layer 12 may be arranged inside the circular holes of the mesh (or net). For example, the second resin layer 12 may be arranged inside the plurality of second openings 1042. Because the shape of the second resin layer 12 may be the same as the shapes of the plurality of second openings 1042, the second resin layer 12 may include a plurality of circular islands.

Referring to the left of FIG. 18, the circular holes (that is, the second openings 1042) may be aligned along the x axis and/or y axis. For example, circular islands of the second resin layer 12 may be aligned along the x axis and/or y axis.

Referring to the right of FIG. 18, the circular holes (that is, the second openings 1042) may be aligned along the x axis and alternate along the y axis. For example, circular islands of the second resin layer 12 may be aligned along the x axis and may alternate along the y axis. In another embodiment, the circular holes (that is, the second holes 1042) or the circular islands of the second resin layer 12 may be aligned along the y axis and may alternate along the x axis. The circular holes (that is, the second openings 1042) and the circular islands of the second resin layer 12 may be arranged closer to each other and in greater numbers within the same (e.g., substantially the same) area in one or more embodiments illustrated on the right side of FIG. 18 than in one or more embodiments illustrated on the left side of FIG. 18.

Referring to FIG. 19, the second opening 1042 of the glass layer 10 may be a hexagonal hole. The glass layer 10 may have a mesh (or net) shape including a plurality of hexagonal holes (that is, the second openings 1042). The second resin layer 12 may be arranged inside the hexagonal holes of the mesh (or net). For example, the second resin layer 12 may be arranged inside the plurality of second openings 1042. Because the shape of the second resin layer 12 may be the same as the shapes of the plurality of second openings 1042, the second resin layer 12 may include a plurality of hexagonal islands.

Referring to the left of FIG. 19, the hexagonal holes (that is, the second openings 1042) may be aligned along the x axis and/or y axis. For example, hexagonal islands of the second resin layer 12 may be aligned along the x axis and/or y axis.

Referring to the right of FIG. 19, the hexagonal holes (that is, the second openings 1042) may be aligned along the x axis and alternate along the y axis. For example, circular islands of the second resin layer 12 may be aligned along the x axis and may alternate along the y axis. In another embodiment, the hexagonal holes (that is, the second holes 1042) or the hexagonal islands of the second resin layer 12 may be aligned along the y axis and may alternate along the x axis. The hexagonal holes (that is, the second openings 1042) and the hexagonal islands of the second resin layer 12 may be arranged closer to each other and in greater numbers within the same (e.g., substantially the same) area in one or more embodiments illustrated on the right side of FIG. 19 than in one or more embodiments illustrated on the left side of FIG. 19.

It will be apparent to those of ordinary skill in the art that the scope of the disclosure is not necessarily limited to the shapes and arrangements shown in FIGS. 17 to 19, and that one or more suitable shapes, sizes, and arrangements may be adopted and/or combined.

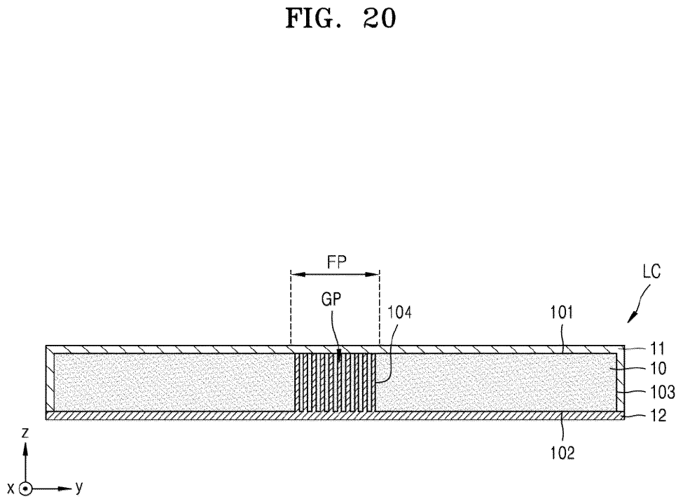

FIG. 20 is a cross-sectional view of the lower cover LC according to one or more embodiments.

Referring to FIG. 20, the first resin layer 11 may be arranged on the first surface 101 and the third surface 103 of the glass layer 10. The first resin layer 11 may cover the first surface 101 and the third surface 103 of the glass layer 10. The second resin layer 12 may be arranged on the second surface 102 of the glass layer 10. The second resin layer 12 may cover the second surface 102 of the glass layer 10. A portion of the second resin layer 12 may be arranged inside the groove 104 of the glass layer 10. The first resin layer 11 and the second resin layer 12 may be in contact with each other near the edge in which the second surface 102 and the third surface 103 of the glass layer 10 meet each other.

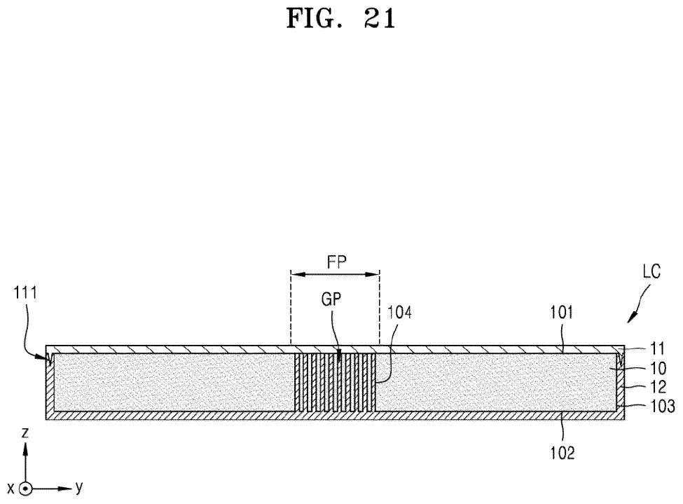

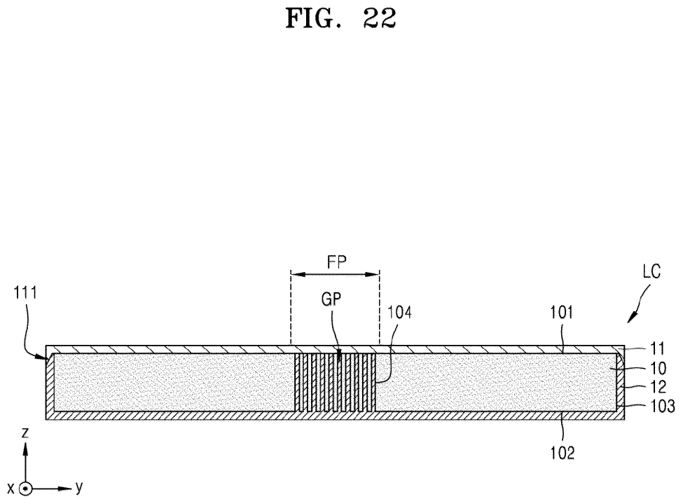

FIG. 21 is a cross-sectional view of the lower cover LC according to one or more embodiments. FIG. 22 is a cross-sectional view of the lower cover LC according to one or more embodiments.

Referring to FIGS. 21 and 22, the first resin layer 11 may include a protrusion 111 protruding toward the second resin layer 12. The protrusion 111 may be arranged adjacent to the third surface 103. In one or more embodiments, the protrusion 111 may be on opposite sides of the glass layer 10.

Referring to FIG. 21, the protrusion 111 may have a nail shape extending along the z axis. For example, the protrusion 111 may have a conical or pyramidal shape. The second resin layer 12 may include an opening overlapping the protrusion 111 of the first resin layer 11, and the protrusion 111 may be received in the opening.

Referring to FIG. 22, the protrusion 111 may represent a portion of a nail, conical, or pyramidal shape. As an example, the protrusion 111 may represent a shape of a nail, a cone, or a pyramid cut in half along the vertical axis (rotational axis). A portion of the protrusion 111 may be open toward the outer surface of the first resin layer 11.

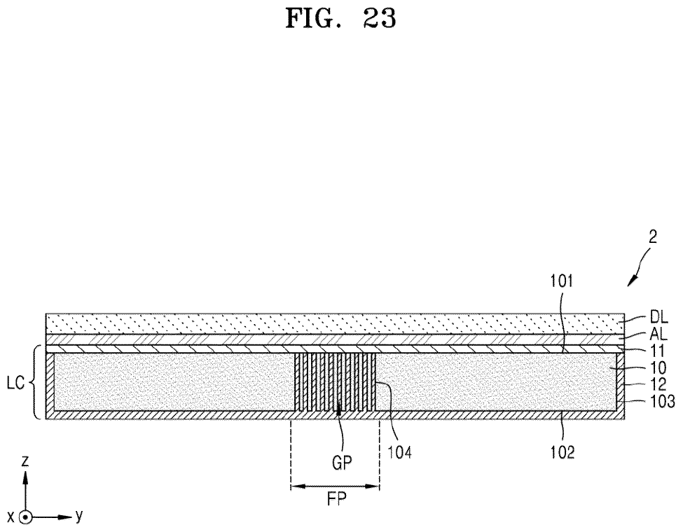

FIG. 23 is a schematic cross-sectional view of the display device 2 according to one or more embodiments.

Referring to FIG. 23, the display layer DL may be arranged on the lower cover LC. The display layer DL may be arranged on the first resin layer 11. For example, the display layer DL may be arranged on the first surface 101 of the glass layer 10. The characteristics of the display layer DL may each independently be the same as those described with reference to FIG. 4. An adhesive layer AL may be arranged between the display layer DL and the first resin layer 11. The adhesive layer AL may include any adhesives suitable in the art without any limitations. As an example, the adhesive layer AL may include a pressure sensitive adhesive PSA.

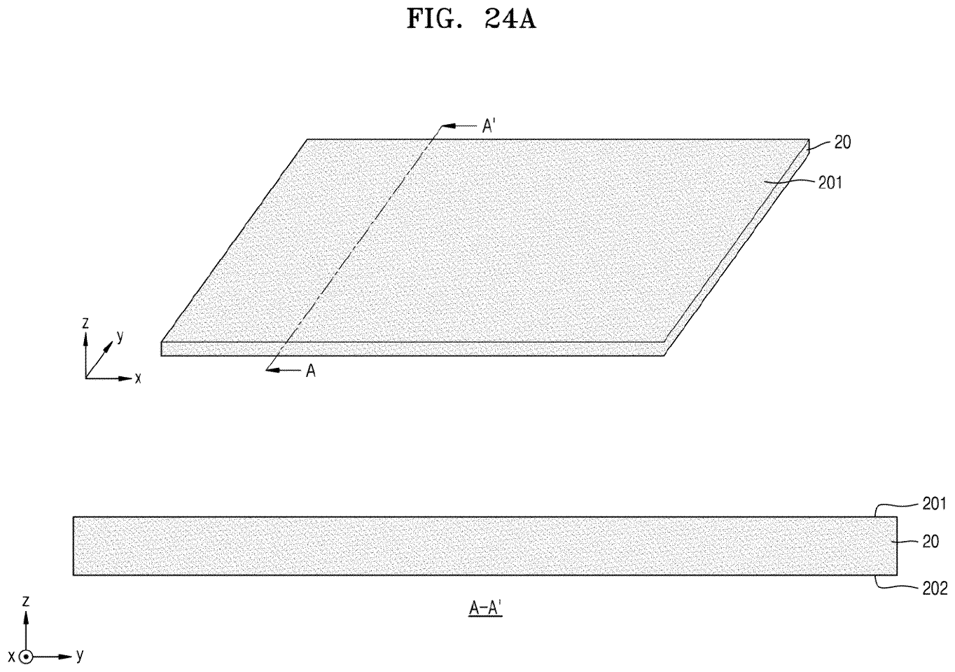

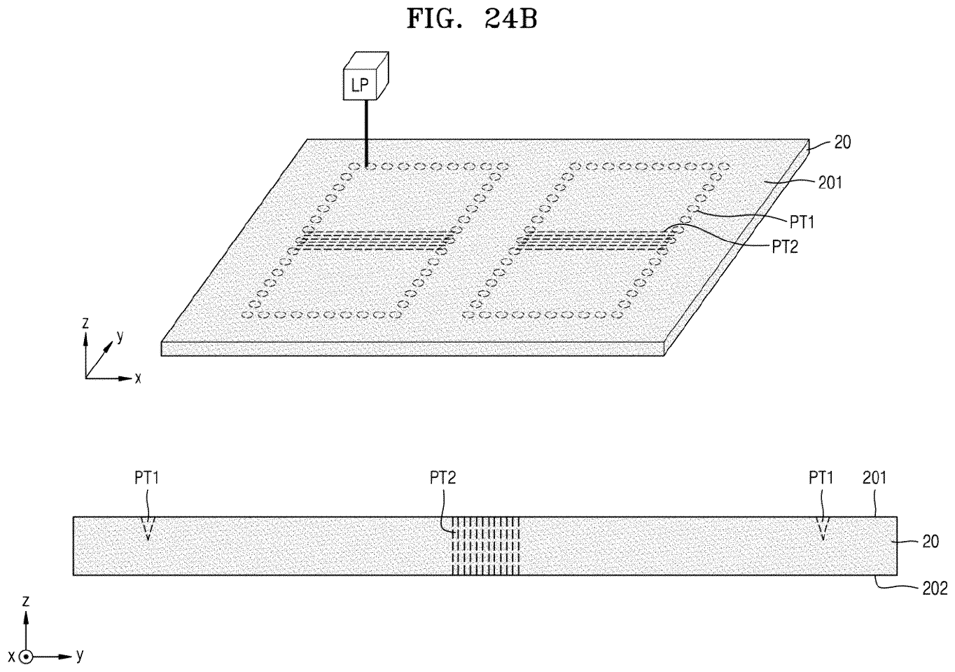

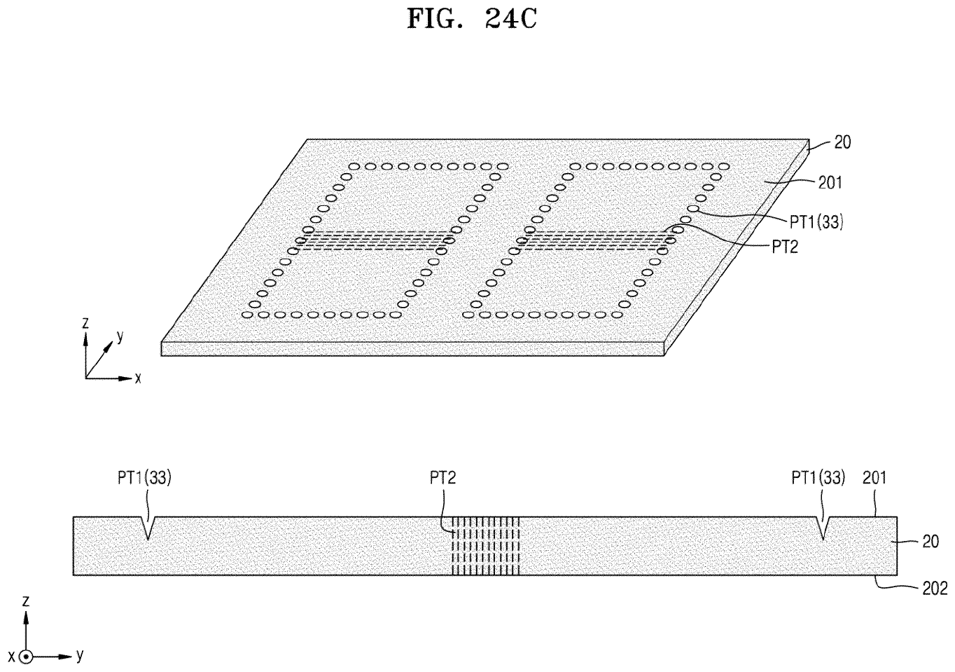

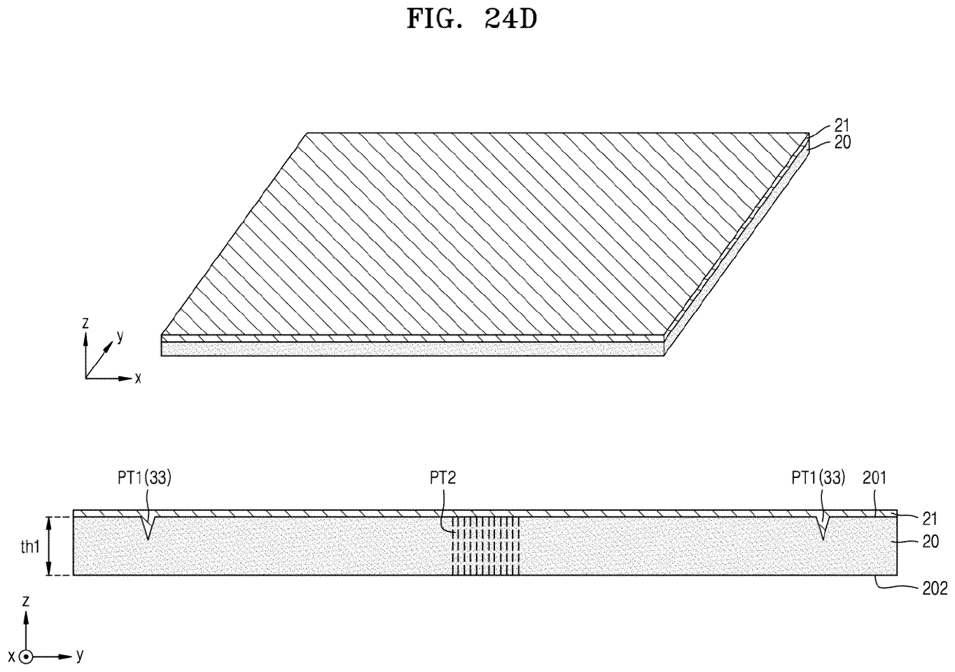

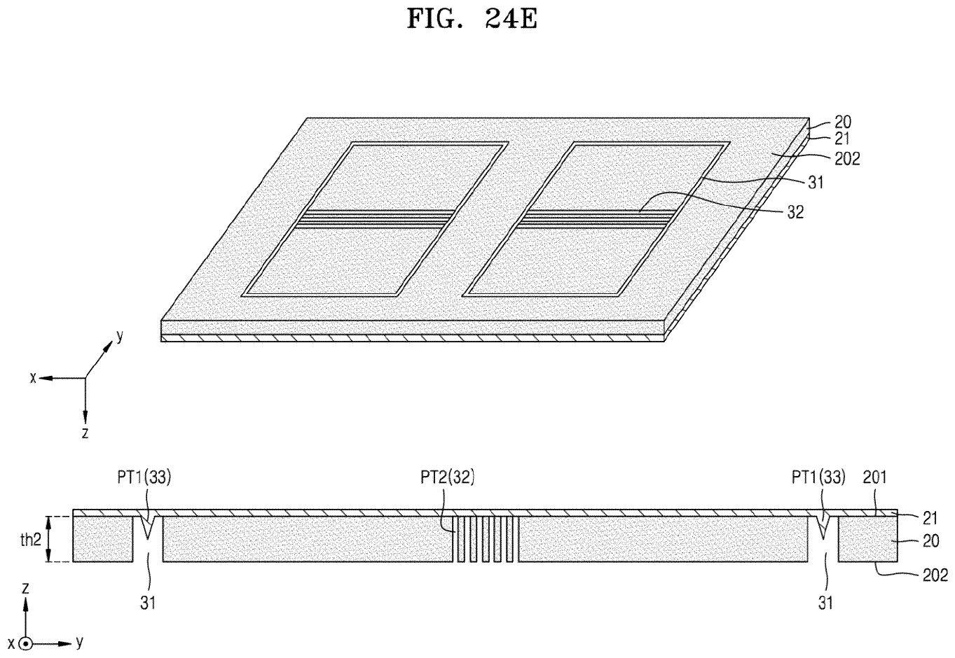

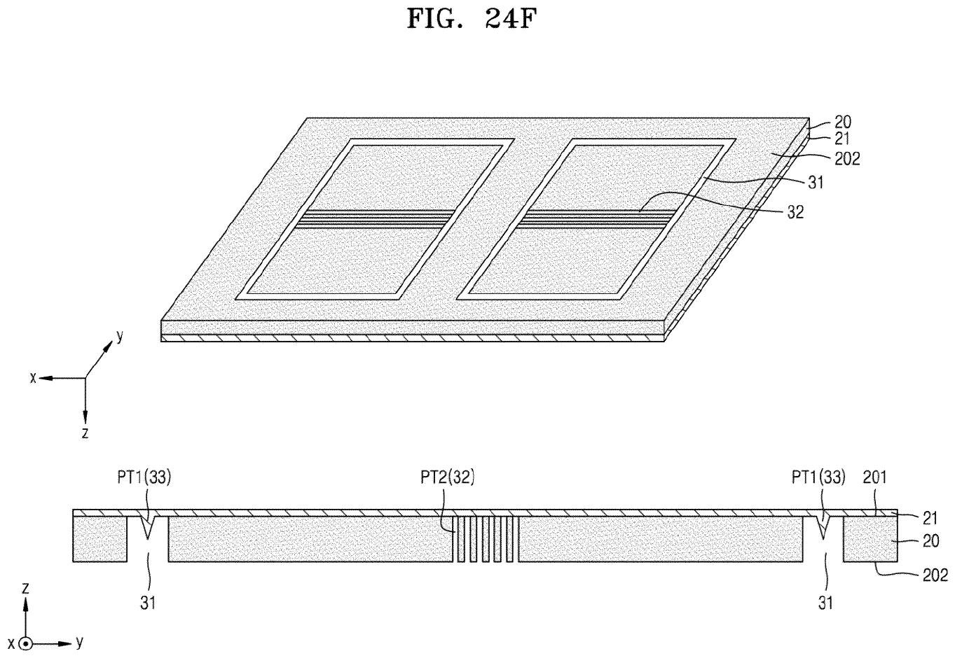

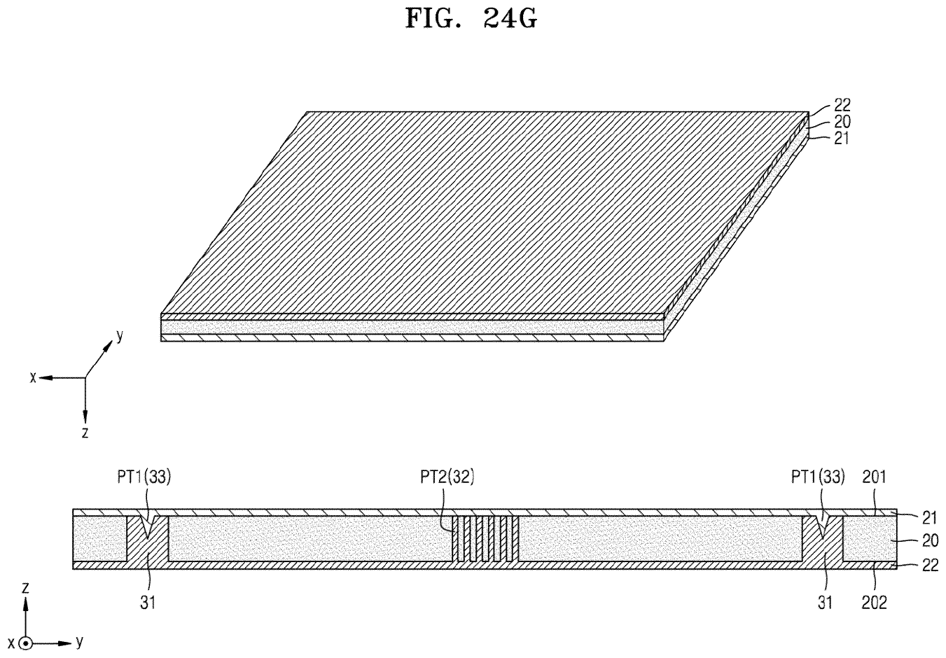

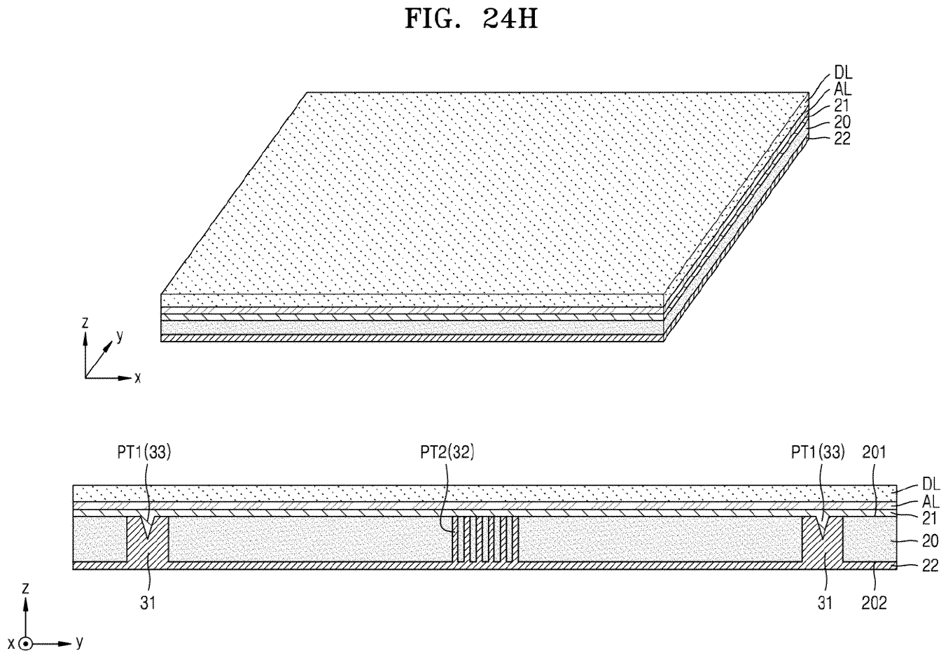

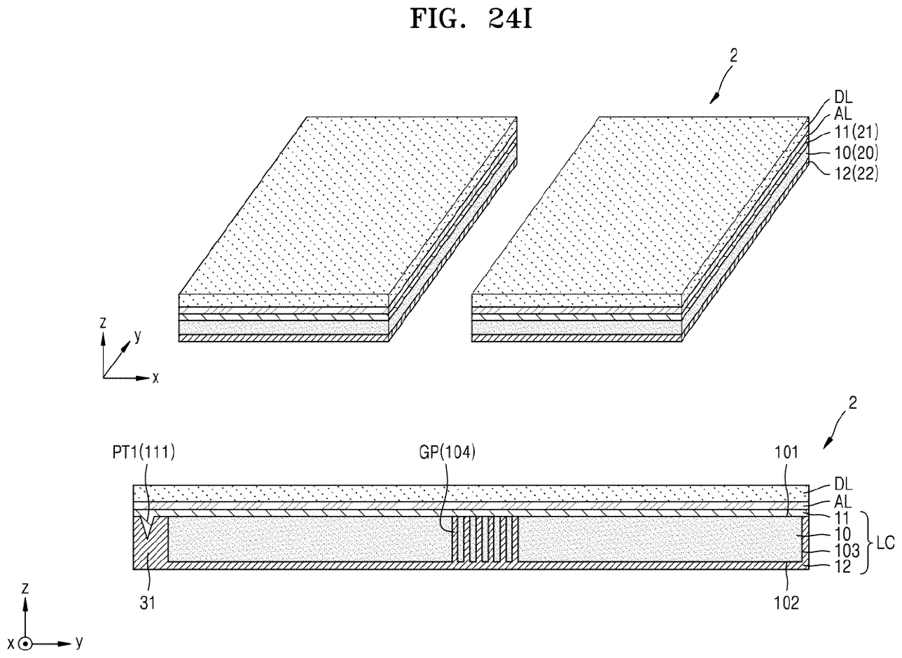

FIGS. 24A to 24I are schematic views showing respective processes of a method of manufacturing a display device according to one or more embodiments. For convenience of illustration and description, each of FIGS. 24A to 24I concurrently (e.g., simultaneously) shows a perspective view and a cross-sectional view of a corresponding process. A cross-sectional view of each of FIGS. 24A to 24I may be a cross-sectional view of a corresponding perspective view, taken along the y axis. As an example, a cross-sectional view of FIG. 24A may be a cross-sectional view of a perspective view of FIG. 24A, taken along the line A-A′.

Referring to FIG. 24A, a glass substrate (e.g., a mother glass substrate) 20 may be prepared. The mother glass substrate 20 may have a first surface 201 and a second surface 202. The second surface 202 may be an opposite surface of the first surface 201. In one or more embodiments, the first surface 201 of the mother glass substrate 20 may be the upper surface of the mother glass substrate 20, and the second surface 202 of the mother glass substrate 20 may be the lower surface of the mother glass substrate 20. The first surface 201 of the mother glass layer 20 may face the z axis direction. The second surface 202 of the mother glass layer 20 may face the opposite direction of the z axis direction. For example, the first surface 201 and the second surface 202 may face opposite directions. In the present specification, detailed description is made on the assumption that the first surface 201 is the upper surface and the second surface 202 is the lower surface. In this case, an expression such as “arranged on the first surface 201” may be also understood as “arranged on (or over) the mother glass layer 20”, and an expression such as “arranged on the second surface 202” may be also understood as “arranged under (or below) the mother glass layer 20”. However, the disclosure is not necessarily limited to these orientations. The first surface 201 and the second surface 202 of the mother glass substrate 20 may respectively correspond to the first surface 101 and the second surface 102 of the glass layer 10 (see FIG. 6).

Referring to FIG. 24B, the mother glass substrate 20 may be laser-processed. As an example, a first pattern PT1 and a second pattern PT2 may be formed in the mother glass substrate 20 using a laser process LP. Although it is shown in FIG. 24B that the second pattern PT2 is formed over the entire thickness of the mother glass substrate 20 in the z axis direction (e.g., a thickness direction) while the first pattern PT1 is not, the disclosure is not necessarily limited thereto. In another embodiment, both (e.g., simultaneously) the first pattern PT1 and the second pattern PT2 may be formed over the entire thickness of the mother glass substrate 20 in the z axis direction (e.g., the thickness direction). The first pattern PT1 may correspond to the circumference of the glass layer 10 (see FIG. 6). The second pattern PT2 may correspond to a glass pattern GP (see FIG. 6) of the glass layer 10 (see FIG. 6). In one or more embodiments, the first pattern PT1 may be processed using laser spots. As an example, the first pattern PT1 may be formed by irradiating spots at regular intervals rather than continuously irradiating a laser beam. However, the disclosure is not necessarily limited thereto and the first pattern PT1 may be formed in a line shape by continuously irradiating a laser beam.

Physical properties of the mother glass substrate 20 may change in a laser-processed region. For example, a portion of the mother glass substrate 20 may be modified by laser processing the mother glass substrate 20. Accordingly, in an etching process of the mother glass substrate 20, an etching selectivity of the mother glass substrate 20 in the region where the first pattern PT1 and the second pattern PT2 are formed may be different from an etching selectivity of the mother glass substrate 20 in other regions. For example, an etching selectivity of the mother glass substrate 20 in the region where the first pattern PT1 and the second pattern PT2 are laser-processed may be different from an etching selectivity of the mother glass substrate 20 in other regions.

In the present specification, the laser processing does not only denote a process of modifying the mother glass substrate 20. In another embodiment, the laser processing may include a process of directly etching the mother glass substrate 20 using a laser beam. In another embodiment, the laser processing may include a process of modifying the mother glass substrate 20 and then etching the modified region of the mother glass substrate 20 using etchant. In the case of directly etching the mother glass substrate 20 using a laser beam or modifying the mother glass substrate 20 using a laser beam and then etching the mother glass substrate 20 using etchant, the first pattern PT1 and the second pattern PT2 may be formed in a recessed shape or opened shape in the mother glass substrate 20. Hereinafter, for convenience of description, a case where a laser processing corresponds to a case of modifying the mother glass substrate 20, that is, the first pattern PT1 and the second pattern PT2 correspond to the modified portion of the mother glass substrate 20 is mainly described.

Referring to FIG. 24C, the first surface 201 of the mother glass substrate 20 may be healed. In one or more embodiments, a third groove 33 corresponding to the first pattern PT1 may be formed. As an example, the third groove 33 may be formed by etching a portion of the mother glass substrate 20. As described above, a selectivity of the mother glass substrate 20 in a region in which the first pattern PT1 is formed may be different from a selectivity of the mother glass substrate 20 in the other regions. Accordingly, the mother glass substrate 20 in a region corresponding to the first pattern PT1 may be selectively etched, and the third groove 33 may be formed. In one or more embodiments, the edge of the mother glass substrate 20 defining the third groove 33 may be processed to be rounded or chamfered.

Referring to FIG. 24D, a first material layer 21 may be arranged on the first surface 201 of the mother glass substrate 20. The first material layer 21 may correspond to the first resin layer 11 (see FIG. 6). The first material layer 21 may entirely cover the first surface 201 of the mother glass substrate 20. A portion of the first material layer 21 may be arranged inside the third groove 33. The first material layer 21 may be arranged using any coating methods suitable in the art without any limitations. As an example, the first material layer 21 may be arranged using slot-die coating or spray coating. In one or more embodiments, the first material layer 21 may be arranged and then cured.

Referring to FIGS. 24D and 24E, the first groove 31 and the second groove 32 may be formed in the second surface 202 of the mother glass substrate 20. The first groove 31 may correspond to the first pattern PT1. The second groove 32 may correspond to the second pattern PT2. For convenience of description, a perspective view of FIG. 24E shows the second surface 202.

The first groove 31 may be formed by etching the mother glass substrate 20 from the second surface 202 based on the position of the first pattern PT1. In one or more embodiments, unlike the first pattern PT1, the first groove 31 may have an integrally extending shape. As an example, the first groove 31 may have a frame shape defining the circumference of the glass layer 10 (see FIG. 6). In one or more embodiments, the first groove 31 may be formed to pass through the mother glass substrate 20. In this case, a portion of the first resin layer 11 arranged inside the third groove 33 may be exposed.

The second groove 32 may be formed to correspond to the second pattern PT2. As described above, a selectivity of the mother glass substrate 20 in a region in which the second pattern PT2 is formed may be different from a selectivity of the mother glass substrate 20 in the other regions. Accordingly, the mother glass substrate 20 in a region corresponding to the second pattern PT2 may be selectively etched, and the second groove 32 may be formed. In this case, the shape of the second groove 32 may entirely correspond to the shape of the second pattern PT2.

The one or more suitable shapes of the groove 104 of the glass pattern GP described with reference to FIGS. 6 to 19 may be implemented by forming the second pattern PT2 through a laser processing and then etching the mother glass substrate 20 along the second pattern PT2 to form the second groove 32 in the process shown in FIG. 24B. For example, the second groove 32 may correspond to the groove 104 (see FIG. 6 as an example) of the glass pattern GP. It would be obvious to those of ordinary skill in the art that the laser processing of FIG. 24B and the etching process of FIG. 24E may be appropriately or suitably controlled or selected to implement the one or more suitable shapes of the groove 104 of the glass pattern GP of FIGS. 6 to 19.

The second groove 32 may be also formed to pass through the mother glass substrate 20, and in this case, a portion of the lower surface of the first resin layer 11 may be exposed.

In one or more embodiments, the mother glass substrate 20 may be slimmed. For example, the thickness of the mother glass substrate 20 may be reduced. As an example, the mother glass substrate 20 in FIG. 24D may have a first thickness th1, and the mother glass substrate 20 in FIG. 24E may have a second thickness th2. The second thickness th2 may be less than the first thickness th1. In one or more embodiments, a target thickness of the mother glass substrate 20 desired or required according to specification of a final product may be the second thickness th2.

When the first resin layer 11 is arranged on the first surface 201 of the mother glass substrate 20, in the case where a sufficient thickness (e.g., the first thickness th1) of the mother glass substrate 20 is secured as shown in FIG. 24D, excellent or suitable surface quality of the first resin layer 11 may be guaranteed. Accordingly, the first resin layer 11 may be arranged while the mother glass substrate 20 has a sufficient thickness (e.g., the first thickness th1), and the mother glass substrate 20 may then be slimmed to a target thickness (e.g., the second thickness th2).

In one or more embodiments, the mother glass substrate 20 having the second thickness th2 may be prepared from the time of preparing the mother glass substrate 20 in an operation shown in FIG. 24A. For example, a process of slimming the mother glass substrate 20 may not be provided.

In one or more embodiments, referring to FIGS. 24B, 24C, and 24D together, the process shown in FIG. 24C, that is, the process of forming the third groove 33 may not be provided. In this case, in the process shown in FIG. 24B, that is, in the process of laser-processing the mother glass substrate 20, similar to the second pattern PT2, the first pattern PT1 may be formed over the entire thickness of the mother glass substrate 20 in the z axis direction. In addition, in this case, in the process shown in FIG. 24D, that is, in the process of disposing the first material layer 210, the first surface 201 of the mother glass substrate 20 may be flat.

Referring to FIG. 24F, the second surface 202 of the mother glass substrate 20 may be healed. In one or more embodiments, the size of the first groove 31 may be increased by additionally etching the mother glass substrate 20 in a region adjacent to the first groove 31. In one or more embodiments, the edge of the mother glass substrate 20 defining the first groove 31 may be processed to be rounded or chamfered.

Referring to FIG. 24G, a second material layer 22 may be arranged on the second surface 202 of the mother glass substrate 20. The second material layer 22 may correspond to the second resin layer 12 (see FIG. 6). The second material layer 22 may entirely cover the second surface 202 of the mother glass substrate 20. A portion of the second material layer 22 may be arranged inside the first groove 31. A portion of the second material layer 22 may be arranged inside the second groove 32. In one or more embodiments, the first groove 31 may be defined to pass through the mother glass substrate 20, and the first material layer 21 and the second material layer 22 may be in contact with each other in a region overlapping the first groove 31. In one or more embodiments, the second groove 32 may be defined to pass through the mother glass substrate 20, and the first material layer 21 and the second material layer 22 may be in contact with each other in a region overlapping the second groove 32. In one or more embodiments, the second material layer 22 may be arranged along the shape of the first material layer 21 that is cured. As an example, a portion of the second material layer 22 arranged inside the first groove 31 may be arranged to match the protruding shape of the first material layer 21 corresponding to the first pattern PT1. The second material layer 22 may be arranged using any coating methods suitable in the art without any limitations. As an example, the second material layer 22 may be arranged through slot die coating or spray coating. In one or more embodiments, the second material layer 22 may be arranged and then cured.

Referring to FIG. 24H, the display layer DL may be arranged over the first surface 201 of the mother glass substrate 20. As an example, the display layer DL may be arranged over the first material layer 21. The characteristics of the display layer DL may each independently be the same as those described with reference to FIG. 4. The adhesive layer AL may be arranged between the display layer DL and the first material layer 21. The adhesive layer AL may include any adhesives suitable in the art without any limitations. As an example, the adhesive layer AL may include a pressure sensitive adhesive PSA.

Referring to FIGS. 24H and 24I, the display device 2 may be implemented by cutting the display layer DL, the first material layer 21, and the second material layer 22. In one or more embodiments, the first material layer 21 and the second material layer 22 may be cut along the first pattern PT1 or the first groove 31. For example, in the cutting process, cutting the mother glass substrate 20 itself does not occur. A portion of the first material layer 21 that is cut may be understood as the first resin layer 11 of the lower cover LC. A portion of the second material layer 22 that is cut may be understood as the second resin layer 12 of the lower cover LC. A portion of the mother glass substrate 20 that is separated (but not cut) may be understood as the glass layer 10 of the lower cover LC.

In one or more embodiments, a portion of a lateral surface of the mother glass substrate 20 defining the first groove 31 may be understood as the third surface 103 of the glass layer 10. Because the second material layer 22 fills the first groove 31, if (e.g., when) forming the second resin layer 12 by cutting the second material layer 22, the third surface 103 of the glass layer 10 may be covered by the second resin layer 12.

It would be obvious to those of ordinary skill in the art that one or more embodiments shown in FIG. 20 may be implemented by appropriately or suitably controlling and cutting the shapes of the first groove 31 and the second groove 32.

In one or more embodiments, cutting may be performed such that a portion of the first material layer 21 corresponding to the first pattern PT1 is included in the lower cover LC, or cutting may be performed such that it is not included. As an example, as shown in the left of the cross-sectional view of FIG. 24I, cutting may be performed such that a portion of the first material layer 21 corresponding to the first pattern PT1 is included in the lower cover LC, and in this case, the portion of the first material layer 21 may be the protrusion 111 of the first resin layer 11. Through this, one or more embodiments shown in FIG. 21 may be implemented. In one or more embodiments, as shown in the right of the cross-sectional view of FIG. 24I, cutting may be performed such that a portion of the first material layer 21 corresponding to the first pattern PT1 is not included in the lower cover LC. In one or more embodiments, one or more embodiments shown in FIG. 22 may be implemented by performing cutting at an appropriate or suitable intermediate point of the first pattern PT1.

In one or more embodiments, the display layer DL, the first material layer 21, and the second material layer 22 may be cut together.

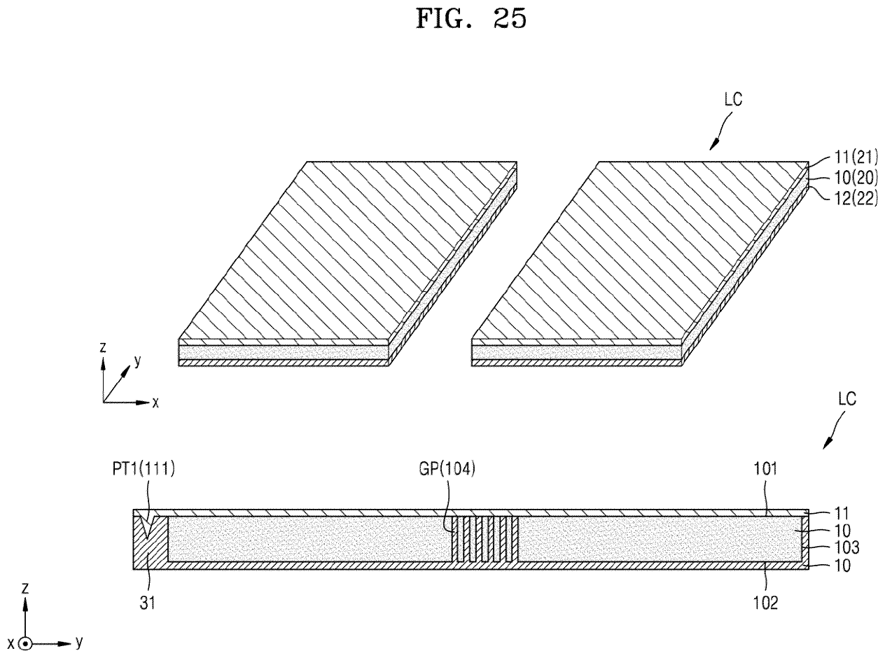

FIG. 25 is a schematic view of a process of a method of manufacturing a display device according to one or more embodiments. For convenience of illustration and description, FIG. 25 concurrently (e.g., simultaneously) shows a perspective view and a cross-sectional view of a corresponding process.

According to one or more embodiments described with reference to FIGS. 24G, 24H, and 24I, the display layer DL may be arranged on the first material layer 21, and then the display layer DL, the first material layer 21, and the second material layer 22 may be cut together.

Referring to FIGS. 24G, 25, and 24I, the first material layer 21 and the second material layer 22 are cut first, and then the display layer DL may be arranged. In this case, it may be understood that the display layer DL is arranged on the first resin layer 11. For example, the lower cover LC is obtained first by cutting the first material layer 21 and the second material layer 22, and the display layer DL corresponding to the individual display device 2 is arranged on the lower cover LC, and thus, the display device 2 may be finally implemented.

Although it is shown in FIGS. 24I and 25 that two display devices 2 are obtained from one mother glass substrate 20, the disclosure is not necessarily limited to this number. The number of lower covers LC and display devices 2 that may be obtained from one mother glass substrate 20 may be appropriately or suitably adjusted according to the size of the mother glass substrate 20, the size and arrangement of the lower cover LC.

According to one or more embodiments, because the surface quality of one or more suitable layers arranged during the manufacturing of the display device may be improved, coating quality may be improved.

According to one or more embodiments, because some of one or more suitable layers arranged during the manufacturing of the display device may not be provided, the thickness of the display device may be reduced.

According to one or more embodiments, because wrinkles that may occur in a region of the display device that is bent or folded may be reduced, the flexibility of the display device may be improved.

Effects of the disclosure are not limited to the above mentioned effects and other effects not mentioned may be clearly understood by those of ordinary skill in the art from the following claims and equivalents thereof.

The display device, the electronic apparatus, the electronic equipment or device, a manufacturing device for the display device, the electronic apparatus, the electronic equipment or device or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

The utilization of “may” when describing embodiments of the present disclosure refers to “one or more embodiments of the present disclosure.”

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, or 5% of the stated value.

In the context of the present application and unless otherwise defined, the terms “use,” “using,” and “used” may be considered synonymous with the terms “utilize,” “utilizing,” and “utilized,” respectively.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

It should be understood that embodiments described herein should be considered in a descriptive sense only and not for purposes of limitation. Descriptions of features or aspects within each embodiment should typically be considered as available for other similar features or aspects in one or more embodiments. While one or more embodiments have been described with reference to the drawings, it will be understood by those of ordinary skill in the art that one or more suitable changes in form and details may be made therein without departing from the spirit and scope as defined by the following claims and equivalents thereof.

What is claimed is:

1. A display device comprising:
a lower cover comprising a glass layer, a first resin layer on a first surface of the glass layer, and a second resin layer on a second surface, the second surface being an opposite surface of the first surface; and
a display layer on the lower cover and comprising a plurality of light-emitting elements,
wherein the lower cover comprises a folding portion that is foldable around one axis,
the glass layer comprises a glass pattern on the folding portion, and
a lateral surface of the glass layer extending between the first surface and the second surface and defining a circumference of the glass layer, the lateral surface of the glass layer being covered by at least one of the first resin layer or the second resin layer.

2. The display device of claim 1, wherein the glass pattern comprises a groove, and a portion of the second resin layer is in the groove of the glass pattern.

3. The display device of claim 2, wherein the groove passes through the glass layer, and the first resin layer and the second resin layer are in contact with each other in a region overlapping the groove.

4. The display device of claim 1, wherein the lateral surface of the glass layer is covered by the second resin layer, and the first resin layer and the second resin layer are in contact with each other at the lateral surface of the glass layer.

5. The display device of claim 4, wherein the first resin layer comprises a protrusion in a region adjacent to the lateral surface of the glass layer, wherein the protrusion protrudes toward the second resin layer.

6. The display device of claim 1, wherein the display layer is on the first resin layer.

7. An electronic device comprising a display device and a cover window on the display device,
wherein the display device comprises:
a lower cover comprising a glass layer, a first resin layer on a first surface of the glass layer, and a second resin layer on a second surface, the second surface being an opposite surface of the first surface; and
a display layer on the lower cover and comprising a plurality of light-emitting elements,
wherein the lower cover comprises a folding region that is foldable around one axis,
the glass layer comprises a glass pattern in the folding region, and
a lateral surface of the glass layer extending between the first surface and the second surface and defining a circumference of the glass layer, the lateral surface being covered by at least one of the first resin layer or the second resin layer.

8. A method comprising:
forming a first pattern and a second pattern on a mother glass substrate by laser processing the mother glass substrate;
arranging a first material layer on a first surface of the mother glass substrate that is laser processed;
forming a first groove and a second groove in a second surface opposite to the first surface of the mother glass substrate on which the first material layer is arranged, wherein the first groove and the second groove respectively overlap the first pattern and the second pattern;
arranging a second material layer on the second surface of the mother glass substrate in which the first groove and the second groove are arranged; and
cutting the first material layer and the second material layer along the first groove,
wherein the method is a method of manufacturing a display device.

9. The method of claim 8, wherein in the arranging of the second material layer, a portion of the second material layer is in the first groove or the second groove.

10. The method of claim 8, wherein at least one of the first groove or the second groove passes through the mother glass substrate.

11. The method of claim 10, wherein the first material layer and the second material layer are in contact with each other in a region overlapping the first groove or the second groove.

12. The method of claim 8, wherein an etching selectivity of a portion of the mother glass substrate on which the first pattern and the second pattern are arranged is different from an etching selectivity of another portion of the mother glass substrate.

13. The method of claim 8, further comprising healing the first surface of the mother glass substrate that is laser processed.

14. The method of claim 13, wherein, in the healing of the first surface of the mother glass substrate, a third groove overlapping the first pattern is arranged, and in the arranging of the first material layer, a portion of the first material layer is in the third groove.

15. The method of claim 8, further comprising healing the second surface of the mother glass substrate in which the first groove and the second groove are arranged.

16. The method of claim 15, wherein, in the healing of the second surface of the mother glass substrate, a size of the first groove is increased.

17. The method of claim 8, further comprising slimming the mother glass substrate.

18. The method of claim 8, further comprising arranging a display layer on the first surface of the mother glass substrate.

19. The method of claim 18, wherein, in the cutting of the first material layer and the second material layer, the display layer is cut together.

20. The method of claim 18, wherein, after the first material layer and the second material layer are cut, the display layer is arranged.
